(19) United States
(12) Patent Application Publication
(10) Pub. No.: US 2024/0113188 A1
(43) Pub. Date: Apr. 4, 2024

(54) INTEGRATED CIRCUIT STRUCTURE AND METHOD FOR FABRICATING THE SAME

(71) Applicant: TAIWAN SEMICONDUCTOR MANUFACTURING COMPANY, LTD., Hsinchu (TW)

(72) Inventors: Wen-Li CHIU, Kaohsiung City (TW); Yi-Juei LEE, Hsinchu City (TW); Yu-Jie YE, Hsinchu City (TW); Chi-Hsin CHANG, Hsinchu City (TW); Chun-Jun LIN, Hsinchu City (TW)

(73) Assignee: TAIWAN SEMICONDUCTOR MANUFACTURING COMPANY, LTD., Hsinchu (TW)

(21) Appl. No.: 18/190,444

(22) Filed: Mar. 27, 2023

Related U.S. Application Data
(60) Provisional application No. 63/378,367, filed on Oct. 4, 2022.

(51) Int. Cl. H01L 29/423; H01L 21/8234; H01L 27/088; H01L 29/06; H01L 29/775

(52) U.S. Cl. CPC H01L 29/4238; H01L 21/823456; H01L 21/823481; H01L 27/088; H01L 29/0673; H01L 29/42392; H01L 29/775

(57) ABSTRACT

An integrated circuit (IC) structure includes a semiconductor substrate, a first gate line, a second gate line, and a first auxiliary gate portion. The semiconductor substrate comprises a semiconductor fin. The semiconductor fin extends substantially along a first direction. The first gate line and the second gate line extend substantially along a second direction different form the first direction from a top view. The first auxiliary gate portion connects the first gate line to the second gate line from the top view.

### PRIORITY CLAIM AND CROSS-REFERENCE

This application claims priority to U.S. Provisional Application Ser. No. 63/378,367, filed Oct. 4, 2022, which is herein incorporated by reference.

### BACKGROUND

The semiconductor integrated circuit (IC) industry has experienced rapid growth. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC manufacturing are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates an integrated circuit (IC) layout according to some embodiments of the present disclosure.

FIG. 1B is a top view of an IC structure fabricating using the IC layout of FIG. 1A.

FIG. 2A illustrates an IC layout according to some embodiments of the present disclosure.

FIG. 2B is a top view of an IC structure fabricating using the IC layout of FIG. 2A.

FIG. 3A illustrates an IC layout according to some embodiments of the present disclosure.

FIG. 3B is a top view of an IC structure fabricating using the IC layout of FIG. 3A.

FIG. 4A illustrates an IC layout according to some embodiments of the present disclosure.

FIG. 4B is a top view of an IC structure fabricating using the IC layout of FIG. 4A.

FIG. 5A illustrates an IC layout according to some embodiments of the present disclosure.

FIG. 5B is a top view of an IC structure fabricating using the IC layout of FIG. 5A.

FIG. 6A illustrates an IC layout according to some embodiments of the present disclosure.

FIG. 6B is a top view of an IC structure fabricating using the IC layout of FIG. 6A.

FIG. 7A illustrates an IC layout according to some embodiments of the present disclosure.

FIG. 7B is a top view of an IC structure fabricating using the IC layout of FIG. 7A.

FIG. 8 illustrates an IC layout according to some embodiments of the present disclosure.

FIGS. 9-15D illustrate various stages of fabricating an IC structure using the IC layout of FIG. 8 according to some embodiments of the present disclosure.

FIGS. 16A-19D illustrate various stages of fabricating an IC structure using the IC layout of FIG. 8 according to some embodiments of the present disclosure.

FIGS. 20A-21D illustrate various stages of fabricating an IC structure using the IC layout of FIG. 8 according to some embodiments of the present disclosure.

FIG. 22 illustrates an IC layout according to some embodiments of the present disclosure.

FIGS. 23A-24D illustrate various stages of fabricating an IC structure using the IC layout of FIG. 22 according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

Structures of the GAA device or the nanosheet device may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As with the other method embodiments and exemplary devices discussed herein, it is understood that parts of the semiconductor device may be fabricated by a CMOS technology process flow, and thus some processes are only briefly described herein. Further, the exemplary semiconductor device may include various other devices and features, such as other types of devices such as additional transistors, bipolar junction transistors, resistors, capacitors, inductors, diodes, fuses, static random access memory (SRAM) and/or other logic circuits, etc., but is simplified for a better understanding of the concepts of the present disclosure. In some embodiments, the exemplary semiconductor device includes a plurality of semiconductor devices (e.g., transistors), including PFETs, NFETs, etc., which may be interconnected.

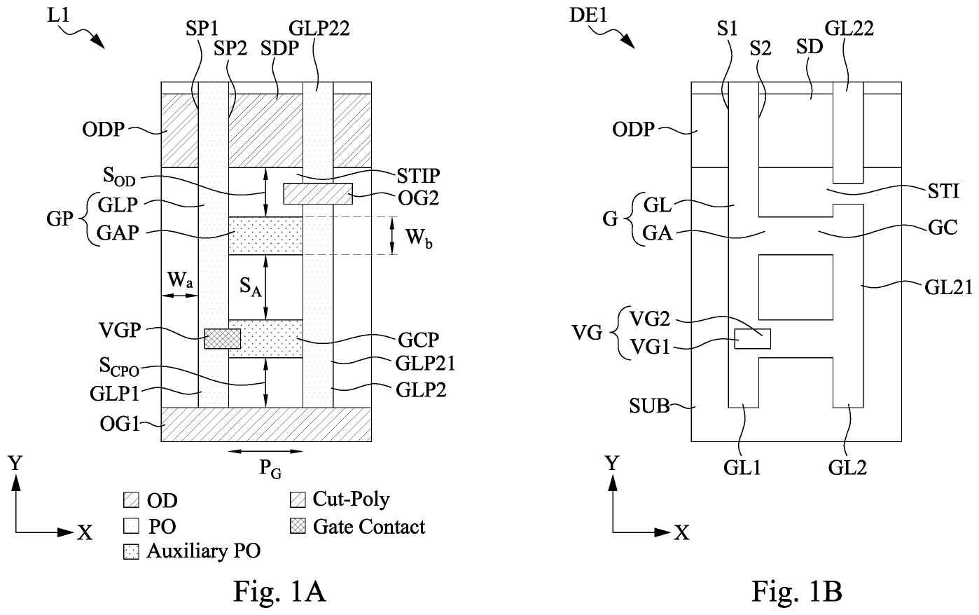

FIG. 1A illustrates an integrated circuit (IC) layout L1 according to some embodiments of the present disclosure. The IC layout L1 may include an oxide-define (OD) layout pattern (also called active region pattern) ODP, a gate layout pattern GP, cut-gate layout patterns OG1 and OG2, and a gate contact layout pattern VGP.

The OD layout pattern ODP defines a corresponding OD region OD of the IC structure DE1 (referring to FIG. 1B). The OD layout pattern ODP extends substantially along a direction of the layout L1, e.g., the direction X. The OD layout pattern ODP is identified in the legend in the drawings with label “OD.” The OD layout pattern ODP includes source region layout patterns and drain region layout patterns (collectively referred to as source/drain region layout patterns SDP that define corresponding source/drain regions SD of the IC structure DE1 (referring to FIG. 1B).

In some embodiments, the OD layout pattern ODP may be separated from another OD layout pattern and other components of the layout L1 on the same layout level by an isolation structure layout pattern STIP. The isolation structure layout pattern STIP defines a corresponding isolation structure STI of the IC structure DE1 (referring to FIG. 1B).

The gate layout pattern GP may include gate line patterns GLP and auxiliary gate patterns GAP. Each of the gate line patterns GLP may extend substantially along the Y direction and be separated from an adjacent one of the gate line patterns GLP in the X direction. The direction Y is different from the direction X. For example, the direction Y is perpendicular to the direction X. Every two adjacent gate line patterns GLP may have a gate pitch P_{G} therebetween along the X direction. The gate pitch P_{G} may be referred to as contacted poly pitch (CPP). In some embodiments, the gate line patterns GLP extend across the OD layout pattern ODP and form active devices. For example, the gate line patterns GLP and corresponding source/drain region layout patterns SDP on opposite sides of the gate line patterns GLP form a plurality of transistors (e.g., FETs). For clear illustration, the two gate line patterns GLP in FIG. 1A are respectively denoted as a gate line pattern GLP1 and a gate line pattern GLP2 extending along the Y direction and parallel with each other.

In the present embodiments, each of the auxiliary gate patterns GAP may include a connecting gate pattern GCP extending substantially along the X direction and connecting at least two (e.g., two or three) adjacent gate line patterns GLP (e.g., gate line patterns GLP1 and GLP2) to each other. For example, as shown in FIG. 1A, each of the gate line pattern GLP (e.g., gate line patterns GLP1 and GLP2) have opposite sidewalls SP1 and SP2, and the connecting gate patterns GCP extend substantially along the X direction from the sidewall SP2 of the gate line pattern GLP1 to the sidewall SP1 of the gate line pattern GLP2.

In some embodiments, each of the gate line patterns GLP has a width Wₐ, each of the auxiliary gate patterns GAP has a width We, and the width We of the auxiliary gate patterns GAP is greater than the width Wₐ of the gate line patterns GLP. For example, a ratio of the width We of the auxiliary gate patterns GAP to the width Wₐ of the gate line patterns GLP may be in a range from about 1.3 to about 1.6. If the ratio of the width We to the width Wₐ is less than about 1.3, the poly line may collapse due to insufficient support to the poly line. If the ratio of the width We to the width Wₐ is greater than about 1.6, the loading issues may become serious in the processes.

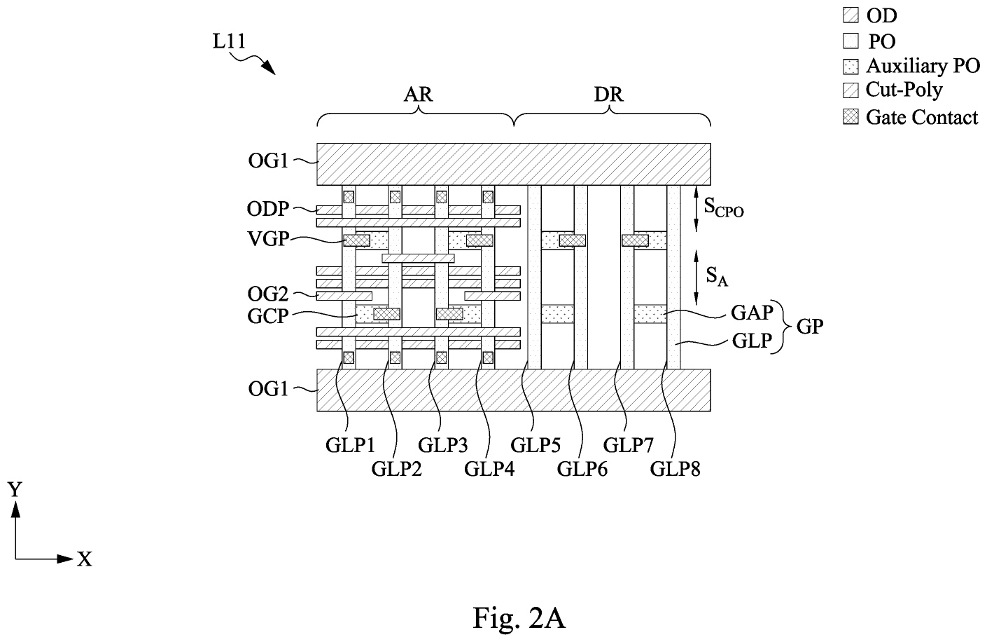

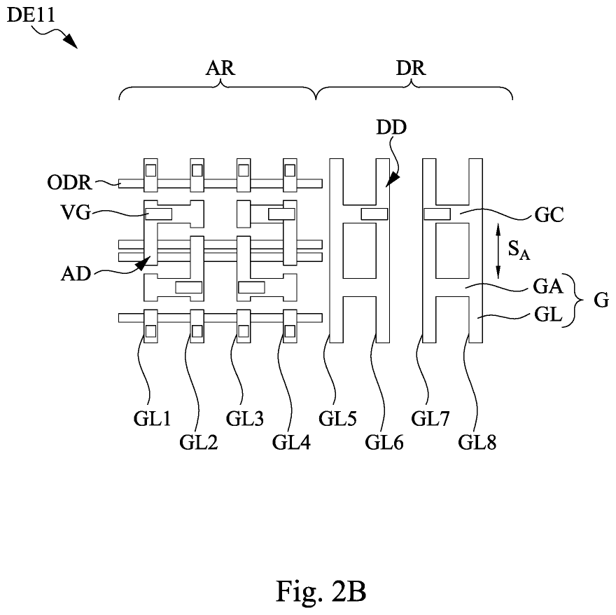

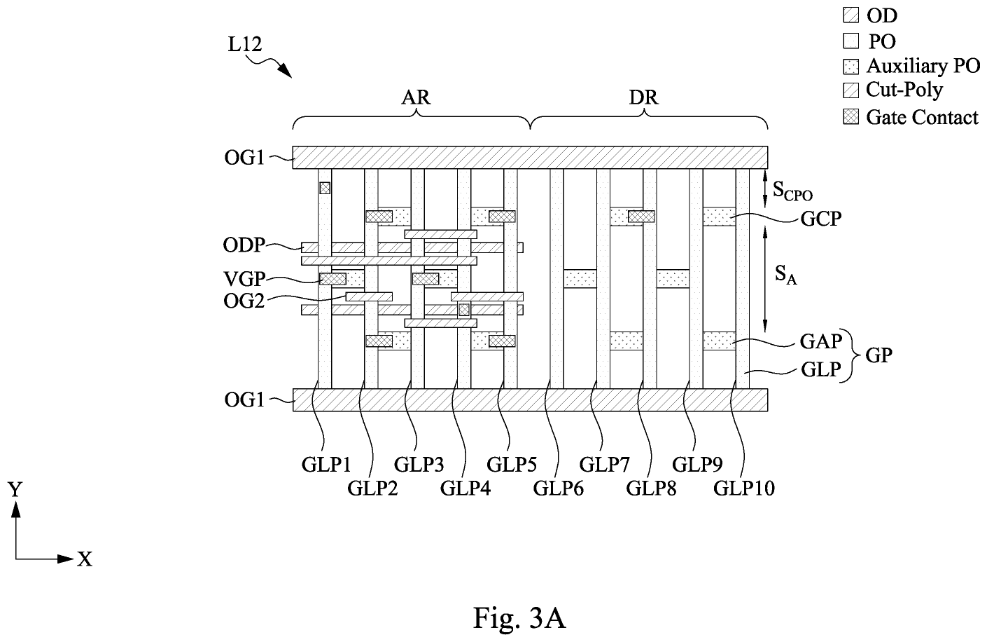

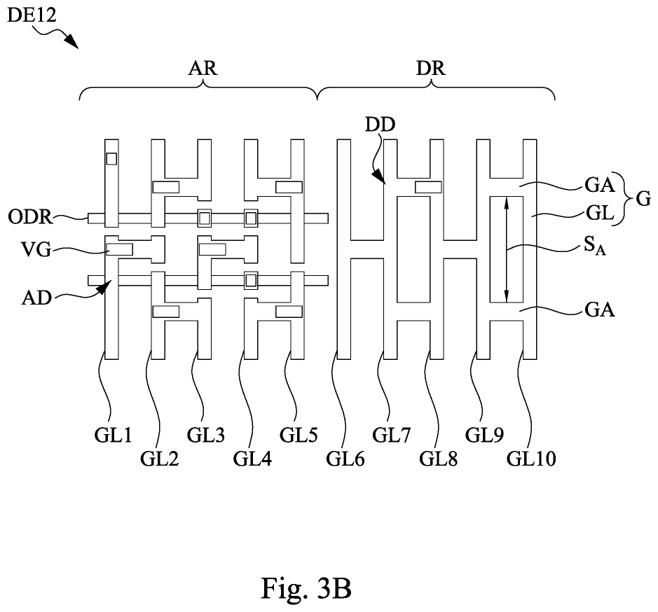

Each of the auxiliary gate patterns GAP (e.g., the connecting gate patterns GCP in the present embodiments) may be separated from an adjacent one of the auxiliary gate patterns GAP (e.g., the connecting gate patterns GCP in the present embodiments) by a distance S_{A} in the Y direction. The distance S_{A} may vary according to the number of connected gate line patterns GLP and/or the distribution of the auxiliary gate patterns GAP, which are illustrated later in FIGS. 2A and 3A. The distance S_{A} may be in a range from about 200 nanometers to about 800 nanometers. If the distance S_{A} is greater than about 800 nanometers, the poly line may collapse due to insufficient support to the poly line. If the distance S_{A} is less than about 200 nanometers, loading issues may become serious in the processes.

The auxiliary gate patterns GAP (e.g., the connecting gate patterns GCP in the present embodiments) may be spaced apart from the OD layout pattern ODP. In some embodiments, one of the auxiliary gate patterns GAP (e.g., connecting gate patterns GCP in the present embodiments) adjacent to the OD layout pattern ODP is spaced apart from said OD layout pattern ODP by a distance S_{OD}. The distance S_{OD} may be in a range from about 300 nanometers to about 500 nanometers. If the distance S_{OD} is greater than about 500 nanometers, poly line may collapse due to insufficient support to the poly line. If the distance S_{OD} is less than about 300 nanometers, since the OD region can provide structural support to the gate structure, the configuration of the auxiliary gate patterns GAP adjacent to OD layout pattern ODP becomes unnecessary, and the auxiliary gate patterns GAP may undesirably affect the electrical performance of the device.

The auxiliary gate patterns GAP (e.g., the connecting gate patterns GCP in the present embodiments) may be spaced apart from the cut-gate layout patterns OG1 and OG2. In some embodiments, one of the auxiliary gate patterns GAP (e.g., the connecting gate patterns GCP in the present embodiments) adjacent to the cut-gate layout pattern OG1/OG2 is spaced apart from said cut-gate layout pattern OG1/OG2 by a distance S_{CPO} greater than or equal to about 25 nanometers. If the distance S_{CPO} is less than about 25 nanometers, materials may not fill the gap between gate structures, or the process window may become poor.

In some embodiments, the gate layout pattern GP including the gate line patterns GLP and the auxiliary gate patterns GAP (e.g., the connecting gate patterns GCP in the present embodiments) are also referred to as POLY layout patterns, in which the gate line patterns GLP are identified in the legend in the drawings with label “PO,” and the auxiliary gate patterns GAP (e.g., the connecting gate patterns GCP in the present embodiments) are identified in the legend in the drawings with label “Auxiliary PO.”

The cut-gate layout patterns OG1 and OG2 may extend substantially along the X direction across the gate line patterns GLP of the gate layout pattern GP. The cut-gate layout patterns OG1 and OG2 represent cut sections or patterning area where the gate line patterns GLP are removed for electrical disconnections according to the integrated circuit design. For example, the cut-gate layout pattern OG1 may cut the gate line patterns GLP1 and GLP2 and indicates a cell boundary of the layout L1. The cut-gate layout patterns OG1 and OG2 extend substantially along the X direction, and thus the cut-gate layout patterns OG1 and OG2 and the OD layout pattern ODP are parallel with each other. In some embodiments, the cut-gate layout patterns OG1 and OG2 are identified in the legend in the drawings with label “Cut-POLY.”

In the present embodiments, the cut-gate layout pattern OG2 cuts the gate line pattern GLP2 into two separate portions GLP21 and GLP22, which are aligned with each other along the Y direction. The portion GLP21 of the gate line pattern GLP2 is connected to the gate line pattern GLP1 by the auxiliary gate patterns GAP (e.g., connecting gate patterns GCP in the present embodiments), and the portion GLP22 of the gate line pattern GLP2 is disconnected from the gate line pattern GLP1. The portion GLP22 may extend across the OD layout pattern ODP, while the portion GL21 may not extend across the OD layout pattern ODP. Through the configuration, the portion GLP22 of the gate line pattern GLP2 which forms a first transistor is electrically isolated from the gate line pattern GLP1 which forms a second transistor.

The gate contact layout pattern VGP may be located on the gate layout pattern GP and may overlap the gate line pattern GLP1 and one of the auxiliary gate patterns GAP (e.g., connecting gate patterns GCP in the present embodiments). For example, the gate contact layout pattern VGP may have a first portion overlapping the gate line pattern GLP1 and a second portion extending beyond a sidewall SP2 of the gate line pattern GLP1 and overlapping one of the auxiliary gate patterns GAP (e.g., connecting gate patterns GCP in the present embodiments). The gate contact layout pattern VGP is identified in the legend in the drawings with label “Gate Contact.”

FIG. 1B is a top view of an IC structure DE1 fabricating using the IC layout L1 of FIG. 1A. The IC structure DE1 inherits geometry of those patterns in the layout L1 of FIG. 1A, as described below. In FIG. 1B, the IC structure DE1 may include a substrate SUB, an oxide-define region ODR, one or more gate structures G, and a gate contact VG.

Various elements of the IC structure DE1 are formed over the substrate SUB. The substrate SUB includes, but is not limited to, a bulk silicon substrate, a silicon-on-insulator (SOI) substrate, or a silicon geranium substrate. Other semiconductor materials including group III, group IV, and group V elements are within the scope of various embodiments.

The oxide-define region (also called active region) ODR corresponds to the pattern ODP in the layout L1 of FIG. 1A. The oxide-define region ODR may be formed by patterning the substrate SUB using photolithography and etching techniques, and thus the resulting oxide-define region ODR are formed of semiconductor materials as well. The oxide-define region ODR can be interchangeably referred to as a semiconductor fin extending upwardly from the substrate SUB in some embodiments of the present disclosure.

The oxide-define region ODR is electrically isolated from another oxide-define region ODR by an isolation structure STI. In some embodiments, the isolation structure STI is a shallow trench isolation (STI) structure including a trench filled with one or more dielectric material. In some embodiments, the STI structure includes silicon dioxide, silicon nitride, silicon oxynitride, or any other suitable insulating materials.

The isolation structure STI corresponds to the pattern STIP in the layout L1 of FIG. 1A. The isolation structure STI may be formed by depositing one or more dielectric materials (e.g., silicon oxide) to completely fill the trenches around the oxide-define region ODR and then recessing the top surface of the dielectric materials to fall below topmost ends of the oxide-define region ODR. The recess process may use, for example, a planarization process (e.g., a chemical mechanical polish (CMP)) followed by a selective etch process (e.g., a wet etch, or dry etch, or a combination thereof) that may recess the top surface of the dielectric materials in the isolation structure STI such that upper portions of the oxide-define region ODR protrude from surrounding insulating isolation structure STI.

The gate structures G correspond to the pattern GP and the patterns OG1 and OG2 in the layout L1 of FIG. 1A. A gate structure G may include gate lines GL and auxiliary gate portions GA. The gate lines GL may extend substantially along the Y direction across the oxide-define region ODR and parallel with each other. The auxiliary gate portions GA are over the isolation structure STI. Each of the auxiliary gate portions GA may include a connecting gate portion GC extending substantially along the X direction and connecting at least two (e.g., two or three) adjacent gate lines GL (e.g., gate lines GL1 and GL2) to each other. For example, the connecting gate portions GC extends substantially along the X direction from a sidewall S2 of the gate line GL1 to a sidewall S1 of the gate line GL2. The auxiliary gate portions GA are spaced apart from the OD region ODR along the Y direction. In some embodiments, the gate line GL1 and/or the gate line GL2 extends beyond opposite sides of the auxiliary gate portions GA along the Y direction. In some embodiments, the gate structures G are poly gate structures. In some embodiments, the gate structures G are high-k metal gate (HKMG) gate structures that may be formed using a gate-last process flow (interchangeably referred to as gate replacement flow). For clear illustration, the two gate lines GL in FIG. 1B are respectively denoted as a gate line GL1 and a gate line GL2 extending along the Y direction and parallel with each other.

The gate line GL2 includes two separated gate line portions GL21 and GL22, which are aligned with each other along the Y direction. The gate line portion GL21 of the gate line GL2 is connected to the gate line GL1 by the auxiliary gate portions GA (e.g., the connecting gate portions GC in the present embodiments), and the gate line portion GL22 of the gate line GL2 is disconnected from the gate line GL1. The gate line portion GL22 may extend across the oxide-define region ODR, while the gate line portion GL21 may not extend across the oxide-define region ODR. Through the configuration, the gate line portion GL22 of the gate line GL2 which forms a first transistor is disconnected from the gate line GL1 which forms a second transistor, thereby avoiding short between the gates of the first and second transistors.

The oxide-define region ODR may include a plurality of source/drain regions SD. In some embodiments, the source/drain regions SD may be doped semiconductor regions located on opposite sides of the corresponding gate lines GL. In some embodiments, the source/drain regions SD include p-type dopants such as boron for formation of p-type FETs. In other embodiments, the source/drain regions SD include n-type dopants such as phosphorus for formation of n-type FETs.

The gate contact VG corresponds to the pattern VGP in the layout L1 of FIG. 1A. The gate contact VG is over the gate structure G. The gate contact VG may have a first portion VG1 overlapping the gate line GL1 and a second portion VG2 extending beyond the sidewall S2 of the gate line GL1 and overlapping one of the auxiliary gate portions GA (e.g., the connecting gate portions GC in the present embodiments). Through the configuration of the auxiliary gate portions GA (e.g., the connecting gate portions GC in the present embodiments), the gate structures G has a larger area for receiving the gate contact VG, a size of the gate contact VG can be increased for enlarging a contact area between the gate contact VG and the gate structure G, thereby reducing resistance.

FIG. 2A illustrates an IC layout L11 according to some embodiments of the present disclosure. In the present embodiments, the gate layout pattern GP of the IC layout L11 uses the auxiliary gate patterns GAP as the connecting gate patterns GCP connected between the gate line patterns GLP as shown in the IC layout L1 (referring to FIG. 1A). The gate line patterns GLP are labelled as gate line patterns GLP1-GLP8 in FIG. 2A. The auxiliary gate patterns GAP establish connections between the gate line patterns GLP1 and GLP2, between the gate line patterns GLP3 and GLP4, between the gate line patterns GLP5 and GLP6, and between the gate line patterns GLP7 and GLP8. The gate line pattern GLP2 is disconnected from the gate line pattern GLP3, the gate line pattern GLP4 is disconnected from the gate line pattern GLP5, and the gate line pattern GLP6 is disconnected from the gate line pattern GLP7.

In FIG. 2A, the auxiliary gate patterns GAP are distributed in a regular arrangement. For example, the auxiliary gate patterns GAP between the gate line patterns GLP1 and GLP2, between the gate line patterns GLP3 and GLP4, between the gate line patterns GLP5 and GLP6, and between the gate line patterns GLP7 and GLP8, are aligned with each other along the X direction.

The IC layout L11 may include an active device region AR accommodating one or more active devices and a dummy device region DR accommodating one or more dummy devices. The active devices may include the OD layout pattern ODP, the gate line patterns GLP1-GLP4 across the OD layout pattern ODP, and the auxiliary gate patterns GAP connected to the gate line patterns GLP1-GLP4. The dummy device region DR may include the gate line patterns GLP5-GLP8 and the auxiliary gate patterns GAP connected to the gate line patterns GLP5-GLP8, and may not include the OD layout pattern ODP. For electrically routing the active devices, plural gate contact layout patterns VGP are formed over the active devices in the active device region AR. The cut-gate layout pattern OG2 are disposed in the active device region AR for avoiding shorting among devices. In some embodiments, suitable gate contact layout patterns VGP may be formed over the dummy devices in the dummy device region DR for providing to suitable stable power (e.g., Vss/Vdd power) to the dummy devices. In some alternative embodiments, the dummy device may be free of the gate contact layout patterns VGP, and the dummy device may be floating. Other details of the present embodiments are similar to those illustrated above, and thereto not repeated herein.

FIG. 2B is a top view of an IC structure DE11 fabricating using the IC layout L11 of FIG. 2A. The IC structure DE11 inherits geometry of those patterns in the layout L11, as described below. As illustrated in FIG. 2A, the auxiliary gate portions GA are distributed in a regular arrangement. For example, the auxiliary gate portions GA between the gate lines GL1 and GL2, between the gate lines GL3 and GL4, between the gate lines GL5 and GL6, and between the gate lines GL7 and GL8, are aligned with each other along the X direction.

The IC structure DE11 may include an active device region AR accommodating one or more active devices AD and a dummy device region DR accommodating one or more dummy devices DD. The active devices AD may include the oxide-defined regions ODR, the gate lines GL1-GL4 across the oxide-defined regions ODR, and the auxiliary gate portions GA connected to the gate lines GL1-GL4. The dummy device region DR may include the gate lines GL5-GL8 and the auxiliary gate portions GA connected to the gate lines GL5-GL8, and may not include the oxide-defined regions ODR. For electrically routing the active devices AD, plural gate contacts VG are formed over the active devices AD in the active device region AR. The gate lines GL1-GL4 are cut into plural portions for avoiding device shorting. In some embodiments, suitable gate contacts VG may be formed over the dummy devices DD in the dummy device region DR for providing to suitable stable power (e.g., Vss/Vdd power) to the dummy devices DD. In some alternative embodiments, the dummy devices DD may be free of the gate contacts VG, and the dummy devices DD may be floating. Other details of the present embodiments are similar to those illustrated above, and thereto not repeated herein.

FIG. 3A illustrates an IC layout L12 according to some embodiments of the present disclosure. The gate layout pattern GP of the IC layout L12 uses the auxiliary gate patterns GAP as the connecting gate patterns GCP connected between the gate line patterns GLP as shown in the IC layout L1 (referring to FIG. 1A). The gate line patterns GLP are labelled as gate line patterns GLP1-GLP10 in FIG. 3A. The auxiliary gate patterns GAP establish a connection between the gate line patterns GLP1-GLP5 and a connection between the gate line patterns GLP6-GLP10. The gate line pattern GLP5 is disconnected from the gate line pattern GLP6.

In FIG. 3A, the auxiliary gate patterns GAP are distributed in a misalignment arrangement. In FIG. 3A, the auxiliary gate patterns GAP between the gate line patterns GLP1 and GLP2, between the gate line patterns GLP3 and GL4, between the gate line patterns GLP6 and GLP7, and between the gate line patterns GLP8 and GLP9, are aligned with each other along the X direction. Also, the auxiliary gate patterns GAP between the gate line patterns GLP2 and GLP3, between the gate line patterns GLP4 and GL5, between the gate line patterns GLP7 and GLP8, and between the gate line patterns GLP9 and GL10, are aligned with each other along the X direction. The auxiliary gate patterns GAP between the gate line patterns GLP3 and GL4, between the gate line patterns GLP6 and GLP7, and between the gate line patterns GLP8 and GLP9, are misaligned with the auxiliary gate patterns GAP between the gate line patterns GLP2 and GLP3, between the gate line patterns GLP4 and GL5, between the gate line patterns GLP7 and GLP8, and between the gate line patterns GLP9 and GL10 along the direction X.

For electrically routing the active devices, plural gate contact layout patterns VGP are formed over the active devices in the active device region AR. The cut-gate layout pattern OG2 are disposed in the active device region AR for avoiding shorting among devices. In some embodiments, suitable gate contact layout patterns VGP may be formed over the dummy devices in the dummy device region DR for providing to suitable stable power (e.g., Vss/Vdd power) to the dummy devices. In some alternative embodiments, the dummy device may be free of the gate contact layout patterns VGP, and the dummy device may be floating. Other details of the present embodiments are similar to those illustrated above, and thereto not repeated herein.

FIG. 3B is a top view of an IC structure DE12 fabricating using the IC layout L12 of FIG. 3A. The IC structure DE12 inherits geometry of those patterns in the layout L12, as described below. For example, the auxiliary gate portions GA are distributed in a misalignment arrangement. The auxiliary gate portions GA between the gate line GL1 and GL2, between the gate line GL3 and GL4, between the gate lines GL6 and GL7, and between the gate lines GL8 and GL9, are misaligned with the auxiliary gate patterns GAP between the gate lines GL2 and GL3, between the gate lines GL4 and GL5, between the gate lines GL7 and GL8, and between the gate lines GL9 and GL10 along the X direction.

The IC structure DE12 may include an active device region AR accommodating one or more active devices AD and a dummy device region DR accommodating one or more dummy devices DD. The active devices AD may include the oxide-defined regions ODR, the gate lines GL1-GL5 across the oxide-defined regions ODR, and the auxiliary gate portions GA connected to the gate lines GL1-GL5. The dummy device region DR may include the gate lines GL6-GL10 and the auxiliary gate portions GA connected to the gate lines GL6-GL10, and may not include the oxide-defined regions ODR. For electrically routing the active devices AD, plural gate contacts VG are formed over the active devices AD in the active device region AR. The gate lines GL1-GL4 are cut into plural portions for avoiding device shorting. In some embodiments, suitable gate contacts VG may be formed over the dummy devices DD in the dummy device region DR for providing to suitable stable power (e.g., Vss/Vdd power) to the dummy devices DD. In some alternative embodiments, the dummy devices DD may be free of the gate contacts VG, and the dummy devices DD may be floating. Other details of the present embodiments are similar to those illustrated above, and thereto not repeated herein.

With reference to FIGS. 2A-3B, the distance S_{A} may vary according to the number of connected gate line patterns GLP (or gate lines GL). When the number of connected gate line patterns GLP (or gate lines GL) increases, the distance S_{A} is allowed to be increased. For example, five gate line patterns GLP (or gate lines GL) are connected to each other by the auxiliary gate patterns GAP (or the auxiliary gate portions GA) in FIGS. 3A and 3B, two gate line patterns GLP (or gate lines GL) are connected to each other by the auxiliary gate patterns GAP (or the auxiliary gate portions GA) in FIGS. 2A and 2B, and the distance S_{A} in FIGS. 3A and 3B is greater than the distance S_{A} in FIGS. 2A and 2B.

Stated differently, the distance S_{A} may vary according to the density of the auxiliary gate patterns GAP (or auxiliary gate portions GA) along the direction X. When the auxiliary gate patterns GAP (or the auxiliary gate portions GA) have a high density along the direction X, the high-density arrangement may provide stronger support to the gate structure, such that the distance S_{A} is allowed to increase. For example, the distance S_{A} in FIGS. 3A and 3B is greater than the distance S_{A} in FIGS. 2A and 2B.

In addition, the distance S_{A} may vary according distribution of the auxiliary gate patterns GAP (or auxiliary gate portions GA). When three or more gate line patterns GLP (or gate lines GL) are connected by the auxiliary gate patterns GAP (or auxiliary gate portions GA), a misalignment arrangement (as shown in FIGS. 3A and 3B) may provide stronger support to the gate structure than an regular arrangement (as shown in FIGS. 2A and 2B). Thus, the distance S_{A} in FIGS. 3A and 3B can be greater than the distance S_{A} in FIGS. 2A and 2B.

In some embodiments, an IC layout (or an IC structure) has plural regions (e.g., the active region AR and the dummy region DR), and the IC layout (or the IC structure) may include different numbers of connected gate line patterns GLP (or gate lines GL), different arrangements of the auxiliary gate patterns GAP (or auxiliary gate portions GA), and/or different distances S_{A} at the different regions. For example, the number of connected gate line patterns GLP (or gate lines GL) in the dummy region DR may be greater than the number of the connected gate line patterns GLP (or gate lines GL) in the active region AR, thereby avoiding poly gate collapse due to the high aspect ratio in the dummy region DR. For example, the auxiliary gate patterns GAP (or auxiliary gate portions GA) in the dummy region DR may be distributed in a misalignment arrangement, and the auxiliary gate patterns GAP (or auxiliary gate portions GA) in the active region AR may be distributed in a regular arrangement, thereby avoiding poly gate collapse due to the high aspect ratio in the dummy region DR. For example, the dummy region DR (referring to FIGS. 2A-3B) may have less distance S_{A} than the active region AR does, thereby avoiding poly gate collapse due to the high aspect ratio in the dummy region DR.

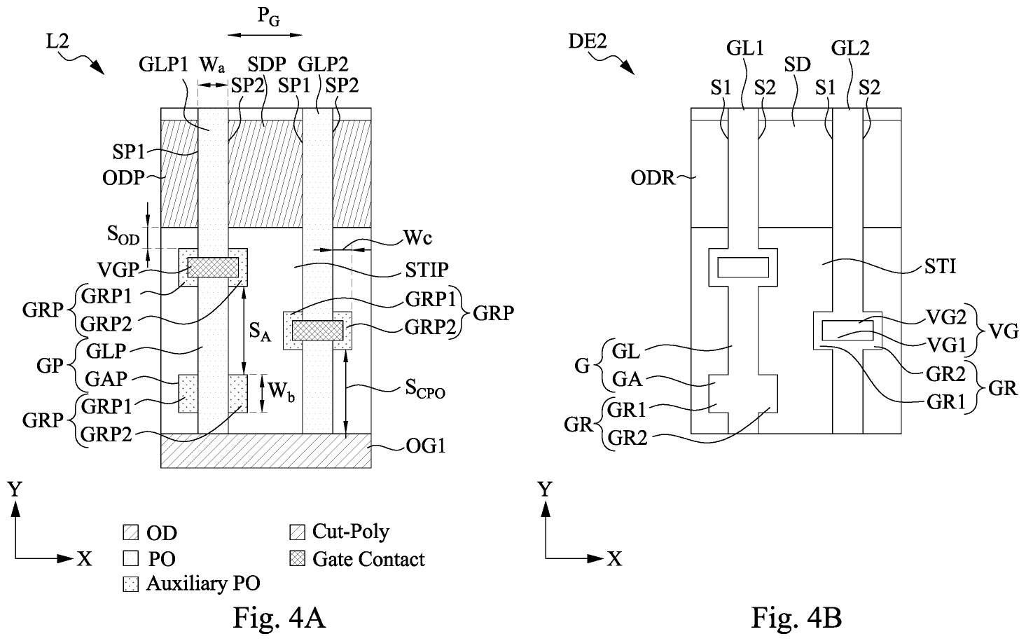

FIG. 4A illustrates an IC layout L2 according to some embodiments of the present disclosure. Details of the IC layout L2 in present embodiments are similar to those illustrated in the IC layout L1 in FIG. 1A, except that the auxiliary gate patterns GAP includes gate rivet patterns GRP, and may not include the connecting gate patterns GCP shown in the IC layout L1 in FIG. 1A.

In the present embodiments, each of the auxiliary gate patterns GAP (e.g., gate rivet patterns GRP in the present embodiments) may extend substantially along the X direction from at least a sidewall of one of the gate line patterns GLP and terminate before reaching a sidewall of a neighboring gate line pattern GLP. For example, a gate rivet pattern GRP neighboring the gate line pattern GLP1 has first and second portions GRP1 and GRP2, in which the first portion GRP1 extends from the first sidewall SP1 of the gate line pattern GLP1 and terminates before reaching a neighboring gate line pattern, and the second portion GRP2 extends from a second sidewall SP2 of the gate line pattern GLP1 and terminates before reaching a first sidewall SP1 of the gate line pattern GLP2. Similarly, a gate rivet pattern GRP neighboring the gate line pattern GLP2 has first and second portions GRP1 and GRP2, in which the first portion GRP1 extends from the first sidewall SP1 of the gate line pattern GLP2 and terminates before reaching the second sidewall SP1 of the gate line pattern GLP1, and a second portion GRP2 extends from the second sidewall SP2 of the gate line pattern GLP2 and terminates before reaching a neighboring gate line pattern. Stated differently, the auxiliary gate patterns GAP (e.g., gate rivet patterns GRP in the present embodiments) may extend from a sidewall SP2/SP1 of the gate line pattern GLP1/GLP2 along a direction toward a gate line pattern GLP2/GLP1 immediately adjacent the sidewall SP2/SP1 of the gate line pattern GLP1/GLP2, but are free of contacting the gate line pattern GLP2/GLP1 immediately adjacent the sidewall SP2/SP1 of the gate line pattern GLP1/GLP2.

In the present embodiments, each of the auxiliary gate patterns GAP (e.g., gate rivet patterns GRP in the present embodiments) may have a width W_{c} greater than about 3 nanometers beyond the sidewall SP1/S02 of the gate line patterns GLP. For example, the W_{c} may be greater than about 5 nanometers. If the width W_{c} is less than about 3 nanometers, the poly line may collapse due to insufficient support to the poly line. For forming the rivet pattern, the width W_{c} can be greater than about 3 nanometers and less than the gate pitch P_{G} between the gate line patterns GLP.

In the present embodiments, the auxiliary gate patterns GAP (e.g., gate rivet patterns GRP) overlapping the gate line patterns GLP1 are misaligned with the auxiliary gate pattern GAP (e.g., gate rivet pattern GRP) overlapping the gate line patterns GLP2 along the X direction. When being misaligned with adjacent auxiliary gate patterns GAP (e.g., gate rivet patterns GRP) along the X direction, the auxiliary gate patterns GAP (e.g., gate rivet patterns GRP) may have the width W_{c} greater than about 3 nanometers and less than about 70% of the gate pitch P_{G} or about 80% of the gate pitch P_{G}.

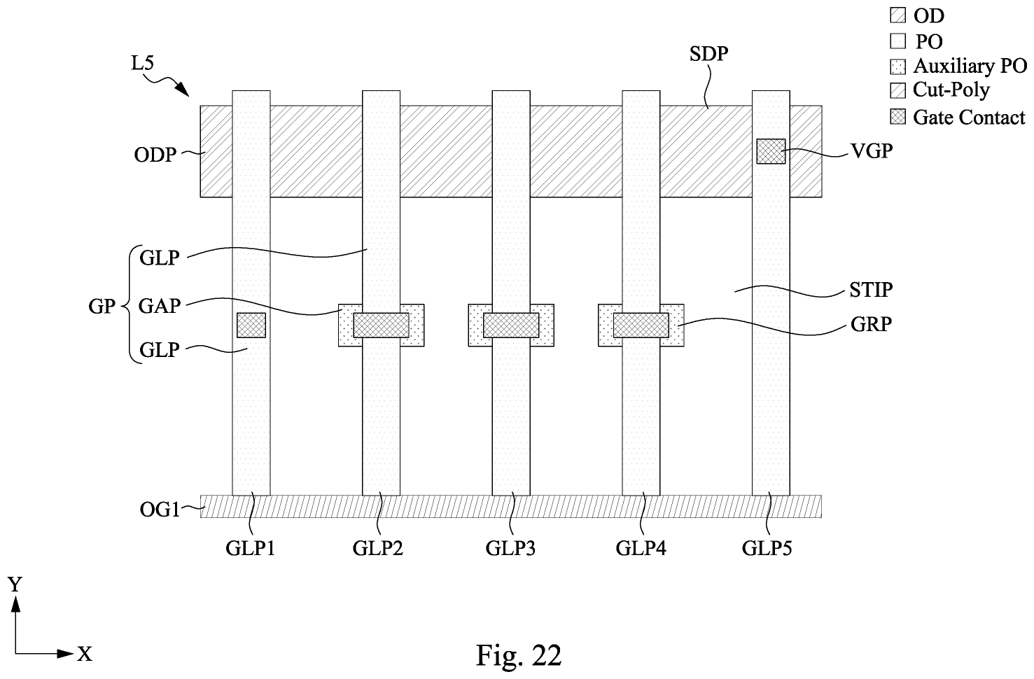

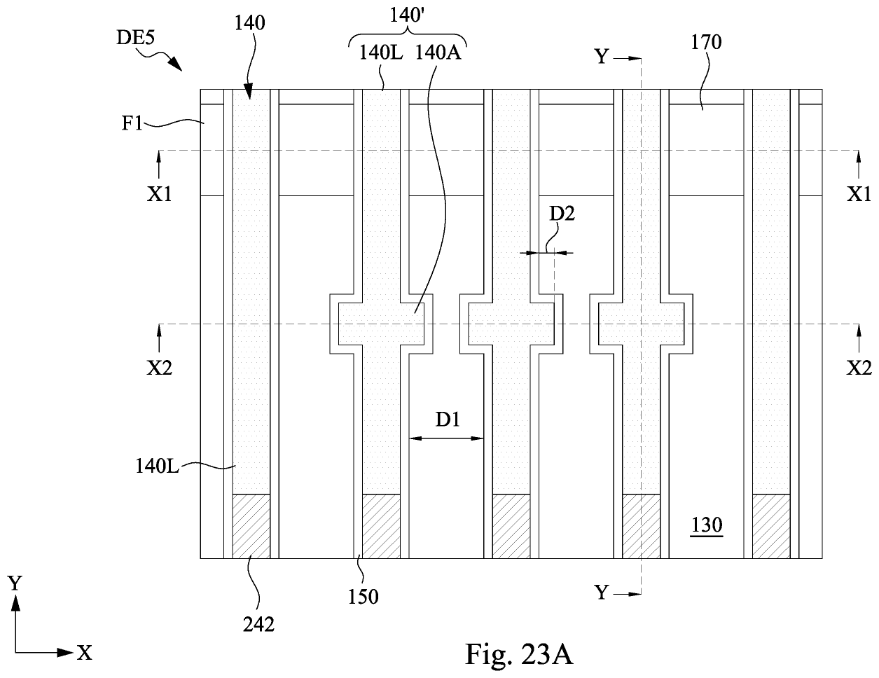

In some other embodiments, the auxiliary gate patterns GAP (e.g., gate rivet patterns GRP) overlapping the gate line patterns GLP1 are aligned with the auxiliary gate pattern GAP (e.g., gate rivet pattern GRP) overlapping the gate line patterns GLP2 along the X direction, as illustrated in FIG. 22 later. When being aligned with each other along the X direction, the auxiliary gate patterns GAP (e.g., gate rivet patterns GRP) may have the width W_{c} greater than about 3 nanometers and less than half the gate pitch P_{G}.

In some embodiments, each of the gate line patterns GLP has a width Wₐ, each of the auxiliary gate patterns GAP has a width We, and the width We of the auxiliary gate patterns GAP is greater than the width Wₐ of the gate line patterns GLP. For example, a ratio of the width We of the auxiliary gate patterns GAP to the width Wₐ of the gate line patterns GLP may be in a range from about 1.3 to about 1.6. If the ratio of the width We to the width Wₐ is less than about 1.3, the poly line may collapse due to insufficient support to the poly line. If the ratio of the width We to the width Wₐ is greater than about 1.6, the loading issues may become serious in the processes.

Each of the auxiliary gate patterns GAP (e.g., the gate rivet patterns GRP in the present embodiments) may be separated from an adjacent one of the auxiliary gate patterns GAP (e.g., the gate rivet patterns GRP in the present embodiments) in the Y direction. Every two adjacent auxiliary gate patterns GAP (e.g., the gate rivet patterns GRP in the present embodiments) may have a distance S_{A} therebetween along the Y direction. The distance S_{A} may vary according to the number of connected gate line patterns GLP, the distribution of the auxiliary gate patterns GAP (e.g., the gate rivet patterns GRP in the present embodiments), as illustrated in FIGS. 2A and 3A. The distance S_{A} may be in a range from about 200 nanometers to about 800 nanometers. If the distance S_{A} is greater than about 800 nanometers, the poly line may collapse due to insufficient support to the poly line. If the distance S_{A} is less than about 200 nanometers, loading issues may become serious in the processes.

The auxiliary gate patterns GAP (e.g., the gate rivet patterns GRP in the present embodiments) may be spaced apart from the OD layout pattern ODP along the Y direction. In some embodiments, one of the auxiliary gate patterns GAP (e.g., the gate rivet patterns GRP in the present embodiments) adjacent to the OD layout pattern ODP is spaced apart from said OD layout pattern ODP by a distance S_{OD}. The distance S_{OD} may be in a range from about 300 nanometers to about 500 nanometers. If the distance S_{OD} is greater than about 500 nanometers, poly line may collapse due to insufficient support to the poly line. If the distance S_{OD} is less than about 300 nanometers, since the OD region can provide structural support to the gate structure, the configuration of the auxiliary gate patterns GAP adjacent to OD layout pattern ODP becomes unnecessary, and the auxiliary gate patterns GAP may undesirably affect the electrical performance of the device.

The auxiliary gate patterns GAP (e.g., the gate rivet patterns GRP in the present embodiments) may be spaced apart from the cut-gate layout patterns OG1 and OG2. In some embodiments, one of the auxiliary gate patterns GAP (e.g., the gate rivet patterns GRP in the present embodiments) adjacent to the cut-gate layout pattern OG1/OG2 is spaced apart from said cut-gate layout pattern OG1/OG2 by a distance S_{CPO} greater than or equal to about 25 nanometers. If the distance S_{CPO} is less than about 25 nanometers, materials may not fill the gap between gate structures, or the process window may become poor.

In some embodiments, the gate layout pattern GP including the gate line patterns GLP and the auxiliary gate patterns GAP (e.g., the gate rivet patterns GRP in the present embodiments) are also referred to as POLY layout patterns, in which the gate line patterns GLP are identified in the legend in the drawings with label “PO,” and the auxiliary gate patterns GAP (e.g., the gate rivet patterns GRP in the present embodiments) are identified in the legend in the drawings with label “Auxiliary PO.” Other details of the present IC layout L2 are similar to those illustrated in the IC layout L1 in FIG. 1A, and thereto not repeated herein.

FIG. 4B is a top view of an IC structure DE2 fabricating using the IC layout L2 of FIG. 4A. The IC structure DE2 inherits geometry of those patterns in the layout L2, as described below. Details of the IC structure DE2 in the present embodiments are similar to the IC structure DE1 illustrated in FIG. 1B, except that the auxiliary gate portions GA include gate rivet portions GR, and may not include the connecting gate portions GC shown in the IC structure DE1 illustrated in FIG. 1B.

The gate structures G correspond to the pattern GP and the patterns OG1 in the layout L2 of FIG. 4A. In the present embodiments, the gate structures G may include gate lines GL and the auxiliary gate portions GA (e.g., the gate rivet portions GR in the present embodiments). The gate lines GL may extend substantially along the Y direction across the oxide-define region ODR and parallel with each other. The auxiliary gate portions GA are over the isolation structure STI. Each of the auxiliary gate portions GA (e.g., the gate rivet portions GR in the present embodiments) may extend substantially along the X direction from at least a sidewall of one of the gate lines GL and terminate before reaching a sidewall of a neighboring gate line. For example, a gate rivet portion GR neighboring the gate line GL1 has first and second portions GR1 and GR2, in which the first portion GR1 extends from the first sidewall S1 of the gate line GL1 and terminates before reaching a neighboring gate line, and the second portion GR2 extends from a second sidewall S2 of the gate line GL1 and terminates before reaching a first sidewall S1 of the gate line GL2. Similarly, a gate rivet portion GR neighboring the gate line pattern GLP2 has first and second portions GR1 and GR2, in which the first portion GR1 extends from the first sidewall S1 of the gate line GL2 and terminates before reaching a second sidewall S2 of the gate line GL1, and the second portion GR2 extends from a second sidewall S2 of the gate line GL2 and terminates before reaching a neighboring gate line. Stated differently, the auxiliary gate portions GA (e.g., gate rivet portions GRP in the present embodiments) may extend from a sidewall S2/S1 of the gate line GL1/GL2 along a direction toward a gate line GL2/GL1 immediately adjacent the sidewall S2/S1 of the gate line GL1/GL2, but are free of contacting the gate line GL2/GL1 immediately adjacent the sidewall S2/S1 of the gate line GL1/GL2. In some embodiments, the gate structures G are high-k metal gate (HKMG) gate structures that may be formed using a gate-last process flow (interchangeably referred to as gate replacement flow).

Through the configuration of the auxiliary gate portions GA (e.g., the gate rivet portions GR in the present embodiments), the gate structures G has a larger area for receiving the gate contact VG, a size of the gate contact VG can be increased for enlarging a contact area between the gate contact VG and the gate structure G, thereby reducing resistance. For example, the gate contact VG may have a first portion VG1 overlapping the gate line GL and one or two second portions VG2 extending beyond the first sidewall S1 and/or the second sidewall S2 of the gate line GL and overlapping the first portion GR1 and/or the second portion GR2 of the gate rivet portions GR. Other details of the present IC structure DE2 are similar to those illustrated in the IC structure DE1 in FIG. 1B, and thereto not repeated herein.

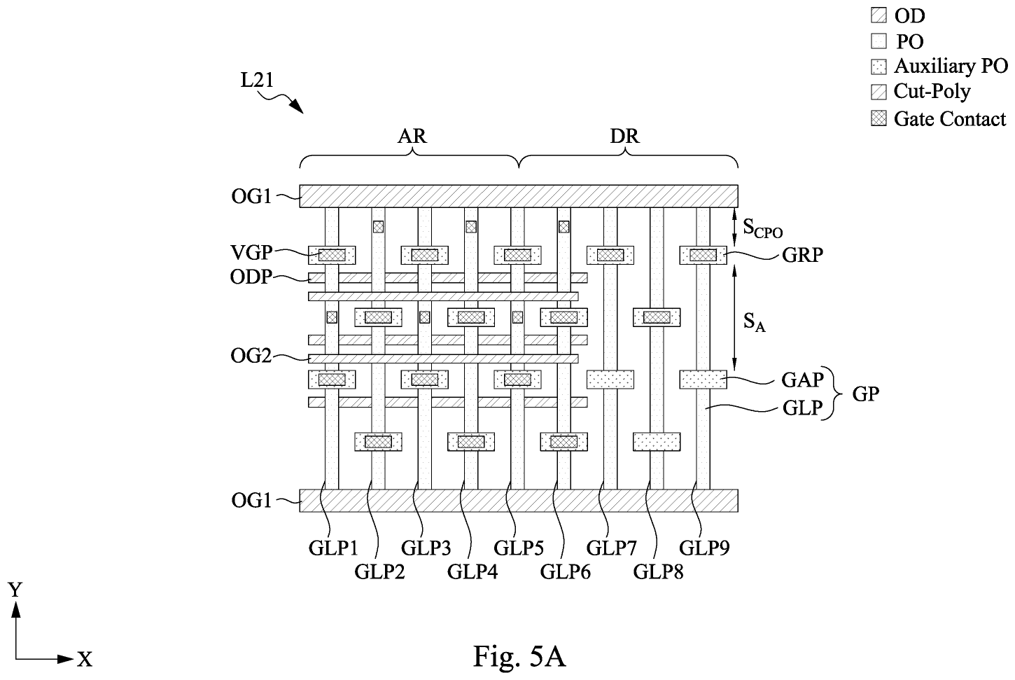

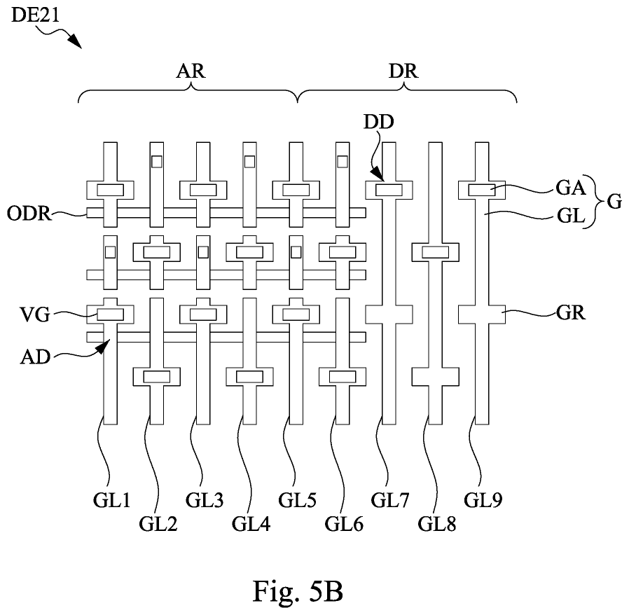

FIG. 5A illustrates an IC layout L21 according to some embodiments of the present disclosure. The gate layout pattern GP of the IC layout L21 uses the auxiliary gate patterns GAP including the gate rivet patterns GRP extending beyond at least a sidewall of the gate line patterns GLP as shown in the IC layout L2 (referring to FIG. 4A). The gate line patterns GLP are labelled as gate line patterns GLP1-GLP9 in FIG. 5A.

In FIG. 5A, the auxiliary gate patterns GAP are distributed in a misalignment arrangement. The For example, the auxiliary gate patterns GAP overlapping the gate line patterns GLP1, GLP3, GLP5, GLP7, and GLP9 are aligned with each other along the X direction. Also, the auxiliary gate patterns GAP overlapping the gate line patterns GLP2, GLP4, GLP6, and GLP8 are aligned with each other along the X direction. The auxiliary gate patterns GAP overlapping the gate line patterns GLP1, GLP3, GLP5, GLP7, and GLP9 are misaligned with the auxiliary gate patterns GAP overlapping the gate line patterns GLP2, GLP4, GLP6, and GLP8 along the X direction.

The IC layout L21 may include an active device region AR accommodating one or more active devices and a dummy device region DR accommodating one or more dummy devices. The active devices may include the OD layout pattern ODP, the gate line patterns GLP1-GLP6 across the OD layout pattern ODP, and the auxiliary gate patterns GAP. The dummy device region DR may include the gate line patterns GLP7-GLP9 and the auxiliary gate patterns GAP, and may not include the OD layout pattern ODP. For electrically routing the active devices, plural gate contact layout patterns VGP are formed over the active devices in the active device region AR. In some embodiments, suitable gate contact layout patterns VGP may be formed over the dummy devices in the dummy device region DR for providing to suitable stable power (e.g., Vss/Vdd power) to the dummy devices. In some alternative embodiments, the dummy device may be free of the gate contact layout patterns VGP, and the dummy device may be floating. Other details of the present embodiments are similar to those illustrated above, and thereto not repeated herein.

FIG. 5B is a top view of an IC structure DE21 fabricating using the IC layout L21 of FIG. 5A. The IC structure DE21 inherits geometry of those patterns in the layout L21, as described below. For example, the auxiliary gate portions GA are distributed in a misalignment arrangement. The auxiliary gate portions GA between the gate lines GL1, GL3, GL5, and GL9 are misaligned with the auxiliary gate patterns GA overlapping the gate line patterns GL2, GL4, GL6, and GL8 along the X direction

The IC structure DE21 may include an active device region AR accommodating one or more active devices AD and a dummy device region DR accommodating one or more dummy devices DD. The active devices AD may include the oxide-defined regions ODR, the gate lines GL1-GL6 across the oxide-defined regions ODR, and the auxiliary gate portions GA connected to the gate lines GL1-GL6. The dummy device region DR may include the gate lines GL7-GL10 and the auxiliary gate portions GA connected to the gate lines GL7-GL10, and may not include the oxide-defined regions ODR. For electrically routing the active devices AD, plural gate contacts VG are formed over the active devices AD in the active device region AR. In some embodiments, suitable gate contacts VG may be formed over the dummy devices DD in the dummy device region DR for providing to suitable stable power (e.g., Vss/Vdd power) to the dummy devices DD. In some alternative embodiments, the dummy devices DD may be free of the gate contacts VG, and the dummy devices DD may be floating. Other details of the present embodiments are similar to those illustrated above, and thereto not repeated herein.

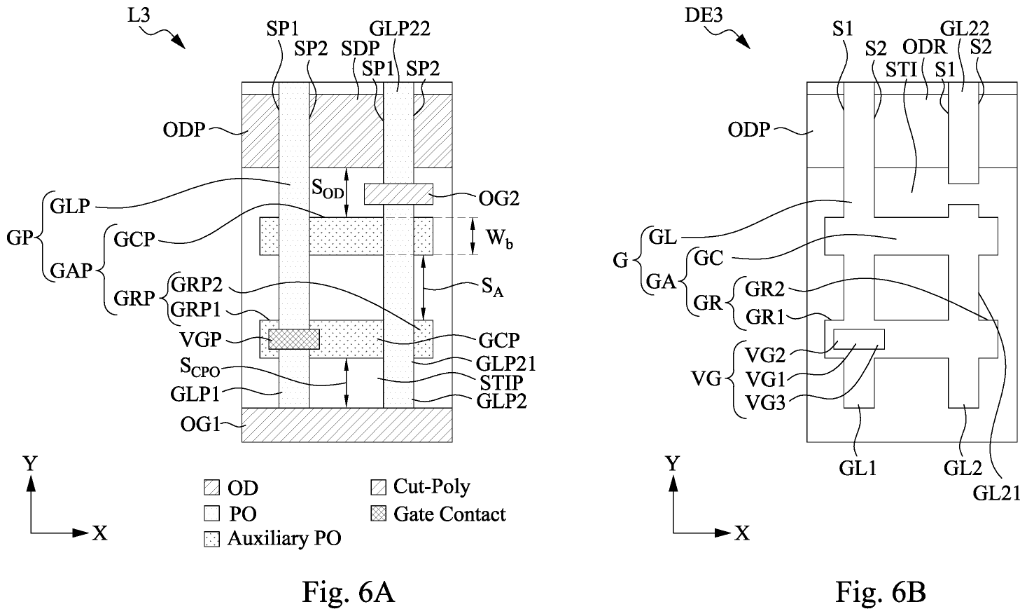

FIG. 6A illustrates an IC layout L3 according to some embodiments of the present disclosure. Details of the IC layout L3 in present embodiments are similar to those illustrated in the IC layout L1 in FIG. 1A and the IC layout L2 in FIG. 4A, except that each of the auxiliary gate patterns GAP includes a connecting gate pattern GCP and a gate rivet pattern GRP (e.g., portions GRP1 and/or GRP2). As aforementioned, each of the connecting gate pattern GCP connects at least two (e.g., two or three) adjacent gate line patterns GLP. For example, the connecting gate patterns GCP extend substantially along the X direction from the sidewall SP2 of the gate line pattern GLP1 to the sidewall SP1 of the gate line pattern GLP2. As aforementioned, the gate rivet patterns GRP extend from a sidewall of one of the gate line patterns GLP and terminate before reaching a sidewall of a neighboring gate line pattern. For example, the portion GRP1 of the gate rivet pattern GRP neighboring the gate line pattern GLP1 extends from the first sidewall SP1 of the gate line pattern GLP1 and terminating before reaching a neighboring gate line pattern. Similarly, the portion GRP2 of the gate rivet pattern GRP neighboring the gate line pattern GLP2 extends from a second sidewall SP2 of the gate line pattern GLP2 and terminating before reaching a neighboring gate line pattern. Other details of the present IC layout L3 are similar to those illustrated in the IC layout L1 in FIG. 1A and the IC layout L2 in FIG. 4A, and thereto not repeated herein.

FIG. 6B is a top view of an IC structure DE3 fabricating using the IC layout L3 of FIG. 6A. The IC structure DE3 inherits geometry of those patterns in the layout L3, as described below. Details of the IC structure DE3 in the present embodiments are similar to the IC structure DE1 illustrated in FIG. 1B and the IC structure DE2 in FIG. 4B, except that each of the auxiliary gate portions GA may include a connecting gate portions GC and a gate rivet portion GR (e.g., portion GR1 and/or GR2). As aforementioned, each of the connecting gate portions GC connects at least two (e.g., two or three) adjacent gate lines GL. For example, the connecting gate portions GC extend substantially along the X direction from the sidewall S2 of the gate line pattern GL1 to the sidewall S1 of the gate line GL2. As aforementioned, the gate rivet portions GR extend from a sidewall of one of the gate lines GL and terminate before reaching a sidewall of a neighboring gate line. For example, the portion GR1 of the gate rivet portion GR neighboring the gate line GL1 may extend from the first sidewall S1 of the gate line GL1 and terminating before reaching a neighboring gate line. Similarly, the portion GR2 of the gate rivet portion GR neighboring the gate line GL2 may extend from a second sidewall S2 of the gate line GL2 and terminating before reaching a neighboring gate line.

Through the configuration of the auxiliary gate portions GA, the gate structures G has a larger area for receiving the gate contact VG, a size of the gate contact VG can be increased for enlarging a contact area between the gate contact VG and the gate structure G, thereby reducing resistance therebetween. In the illustrated examples, the gate contact VG may have a first portion VG1 overlapping the gate line GL, a second portion VG2 extending beyond the first sidewall S1 of the gate line GL1 and overlapping the gate rivet portions GR, and a third portion VG3 extending beyond the second sidewall S2 of the gate line GL1 and overlapping the connecting gate portions GC. Other details of the present IC layout L3 are similar to those illustrated in the IC layout L1 in FIG. 1A and the IC layout L2 in FIG. 4A, and thereto not repeated herein.

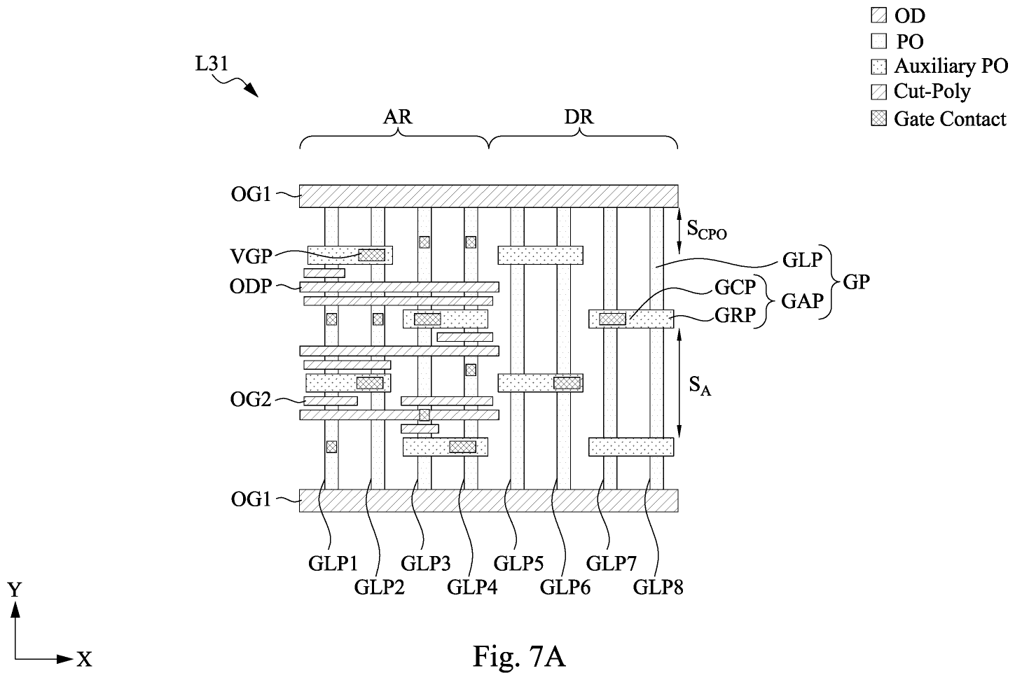

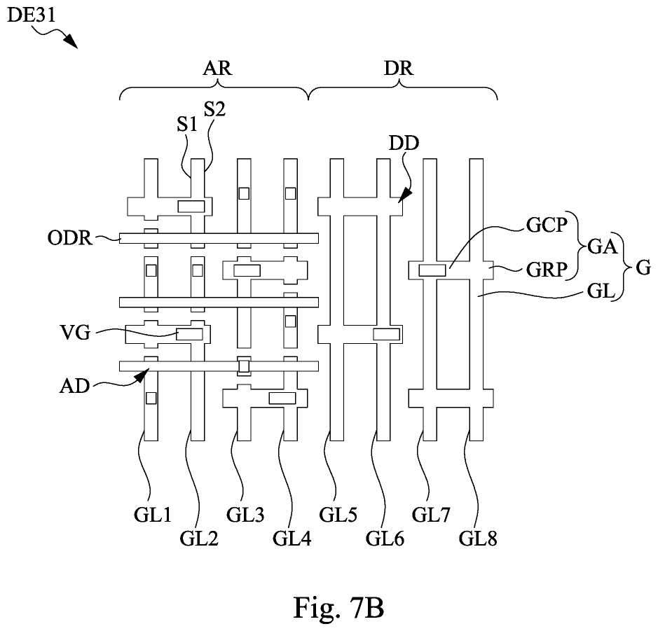

FIG. 7A illustrates an IC layout L31 according to some embodiments of the present disclosure. The IC layout L31 uses the auxiliary gate patterns GAP as shown in the IC layout L3 (referring to FIG. 6A), in which the auxiliary gate patterns GAP include the connecting gate patterns GCP and the gate rivet patterns GRP. The gate line patterns GLP are labelled as gate line patterns GLP1-GLP8 in FIG. 7A. The auxiliary gate patterns GAP establish connections between the gate line patterns GLP1 and GLP2, between the gate line patterns GLP3 and GLP4, between the gate line patterns GLP5 and GLP6, and between the gate line patterns GLP7 and GLP8. The gate line pattern GLP2 is disconnected from the gate line pattern GLP3, the gate line pattern GLP4 is disconnected from the gate line pattern GLP5, and the gate line pattern GLP6 is disconnected from the gate line pattern GLP7.

In FIG. 7A, the auxiliary gate patterns GAP are distributed in a misalignment arrangement. In FIG. 7A, the auxiliary gate patterns GAP between the gate line patterns GLP1 and GLP2 and between the gate line patterns GLP5 and GLP6 are aligned with each other along the X direction. The auxiliary gate patterns GAP between the gate line patterns GLP3 and GL4 and between the gate line patterns GLP7 and GL8 are aligned with each other along the X direction. The auxiliary gate patterns GAP between the gate line patterns GLP1 and GLP2 and between the gate line patterns GLP5 and GLP6 are misaligned with the auxiliary gate patterns GAP between the gate line patterns GLP3 and GL4 and between the gate line patterns GLP7 and GL8 along the direction X.

The IC layout L31 may include an active device region AR accommodating one or more active devices and a dummy device region DR accommodating one or more dummy devices. The active devices may include the OD layout pattern ODP, the gate line patterns GLP1-GLP4 across the OD layout pattern ODP, and the auxiliary gate patterns GAP connected to the gate line patterns GLP1-GLP4. The dummy device region DR may include the gate line patterns GLP5-GLP8 and the auxiliary gate patterns GAP connected to the gate line patterns GLP5-GLP8, and may not include the OD layout pattern ODP. For electrically routing the active devices, plural gate contact layout patterns VGP are formed over the active devices in the active device region AR. The cut-gate layout pattern OG2 are disposed in the active device region AR for avoiding shorting among devices. In some embodiments, suitable gate contact layout patterns VGP may be formed over the dummy devices in the dummy device region DR for providing to suitable stable power (e.g., Vss/Vdd power) to the dummy devices. In some alternative embodiments, the dummy device may be free of the gate contact layout patterns VGP, and the dummy device may be floating. Other details of the present embodiments are similar to those illustrated above, and thereto not repeated herein.

FIG. 7B is a top view of an IC structure DE31 fabricating using the IC layout L31 of FIG. 7A. The IC structure DE31 inherits geometry of those patterns in the layout L31, as described below. The gate lines GL are labelled as gate lines GL1-GL8 in FIG. 7B. The gate line GL2 has two opposite sidewalls S1 and S2, and the gate lines GL1 and GL3 are respectively immediately adjacent to the sidewalls S1 and S2. The auxiliary gate portion GA may connect the gate line GL2 to the gate line GL1 and free of contacting the gate line GL3.

In the present embodiments, the auxiliary gate portions GA are distributed in a misalignment arrangement. The auxiliary gate portions GA between the gate line GL1 and GL2 and between the gate lines GL5 and GL6 are misaligned with the auxiliary gate patterns GAP between the gate lines GL3 and GL4 and between the gate lines GL7 and GL8 along the X direction.

The IC structure DE31 may include an active device region AR accommodating one or more active devices AD and a dummy device region DR accommodating one or more dummy devices DD. The active devices AD may include the oxide-defined regions ODR, the gate lines GL1-GL4 across the oxide-defined regions ODR, and the auxiliary gate portions GA connected to the gate lines GL1-GL4. The dummy device region DR may include the gate lines GL5-GL8 and the auxiliary gate portions GA connected to the gate lines GL5-GL8, and may not include the oxide-defined regions ODR. For electrically routing the active devices AD, plural gate contacts VG are formed over the active devices AD in the active device region AR. The gate lines GL1-GL4 are cut into plural portions for avoiding device shorting. In some embodiments, suitable gate contacts VG may be formed over the dummy devices DD in the dummy device region DR for providing to suitable stable power (e.g., Vss/Vdd power) to the dummy devices DD. In some alternative embodiments, the dummy devices DD may be free of the gate contacts VG, and the dummy devices DD may be floating. The gate contacts VG may be located on the auxiliary gate portions GA (e.g., the connecting gate portions GC and/or the gate rivet portions GR), thereby enlarging a contact area and lowering resistance. Other details of the present embodiments are similar to those illustrated above, and thereto not repeated herein.

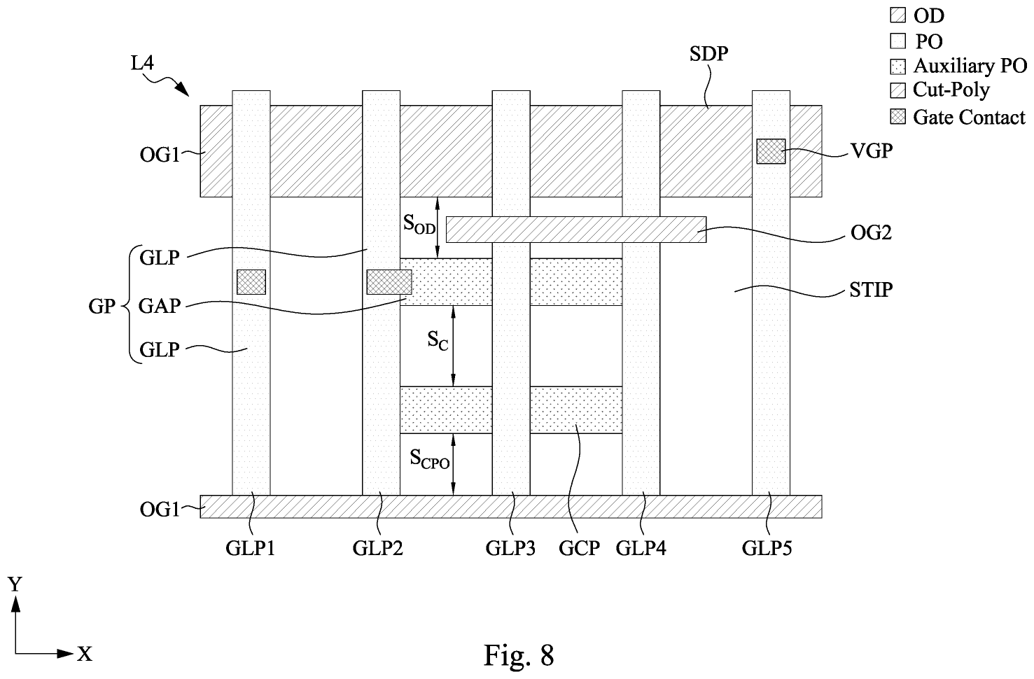

FIG. 8 illustrates an IC layout L4 according to some embodiments of the present disclosure. Details of the IC layout L4 are similar to those illustrated in IC layout L1 of FIG. 1A, except that each of the auxiliary gate patterns GAP (e.g., the connecting gate patterns GCP) may connect three adjacent gate line patterns GLP to each other. The gate line patterns GLP are labelled as gate line patterns GLP1-GLP5 extending substantially along the Y direction. Each of the auxiliary gate patterns GAP (e.g., the connecting gate patterns GCP) may connect the gate line patterns GLP2-GLP4 to each other, and the gate line patterns GLP1 and GLP5 may be spaced apart from the connecting gate patterns GCP. Other details of the present embodiments are similar to those illustrated above, and thereto not repeated herein.

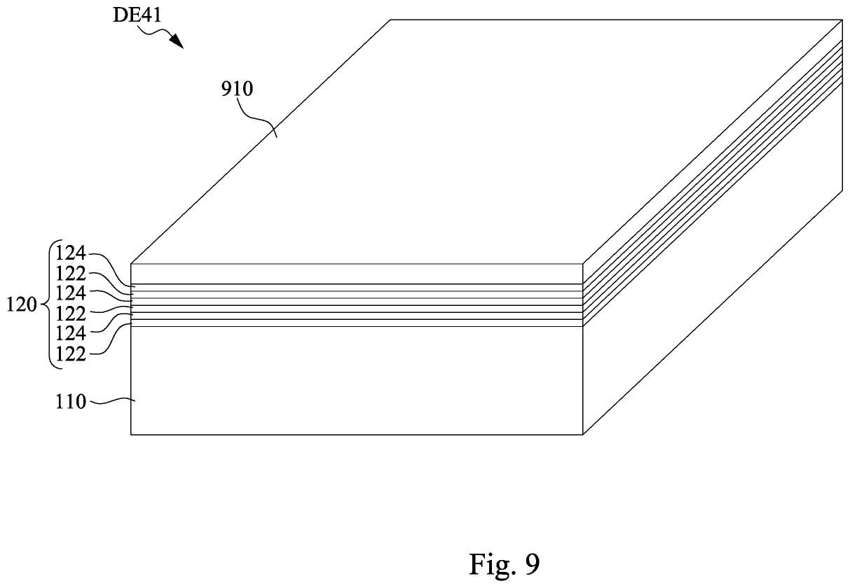

FIGS. 9-15D illustrate various stages of fabricating an IC structure DE41 using the IC layout L4 of FIG. 8 according to some embodiments of the present disclosure. The IC structure DE41 inherits geometry of those patterns in the layout L4 of FIG. 8. It is understood that additional operations may be provided before, during, and after the operations shown by FIGS. 9-15D, and some of the operations described below can be replaced or eliminated for additional embodiments of the method. The order of the operations/processes may be interchangeable.

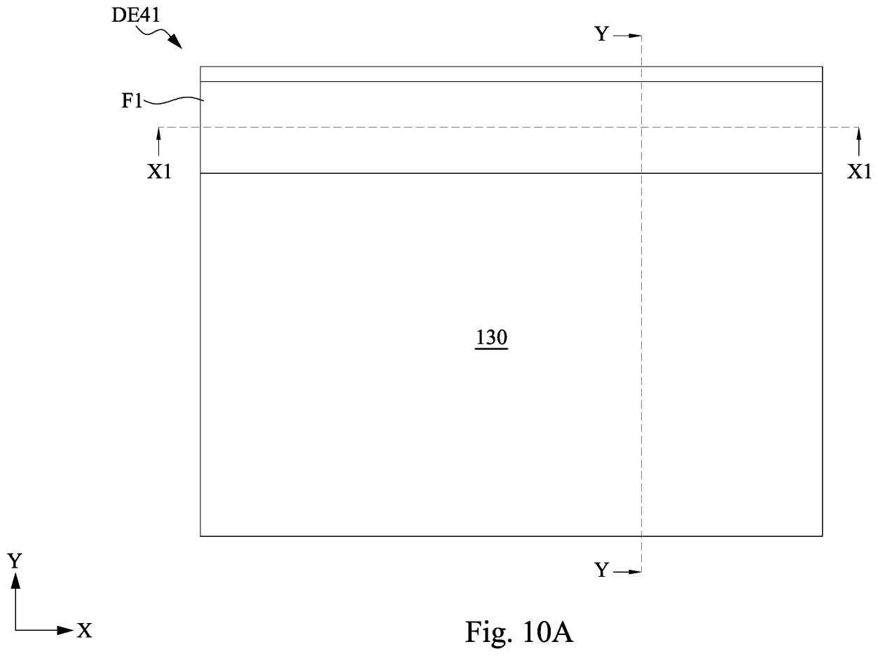

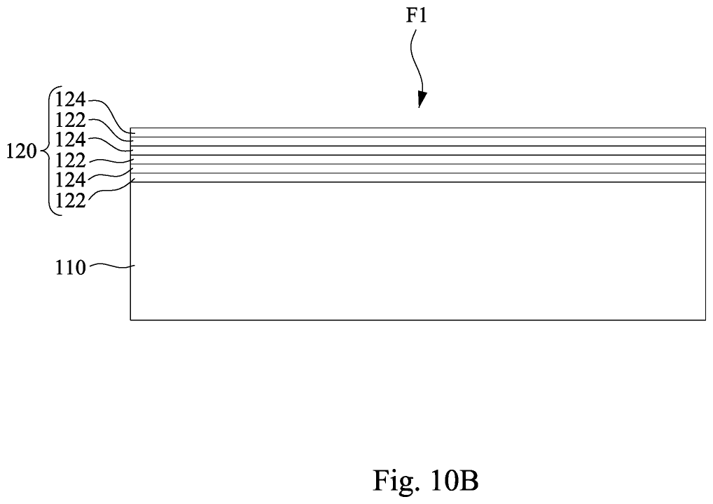

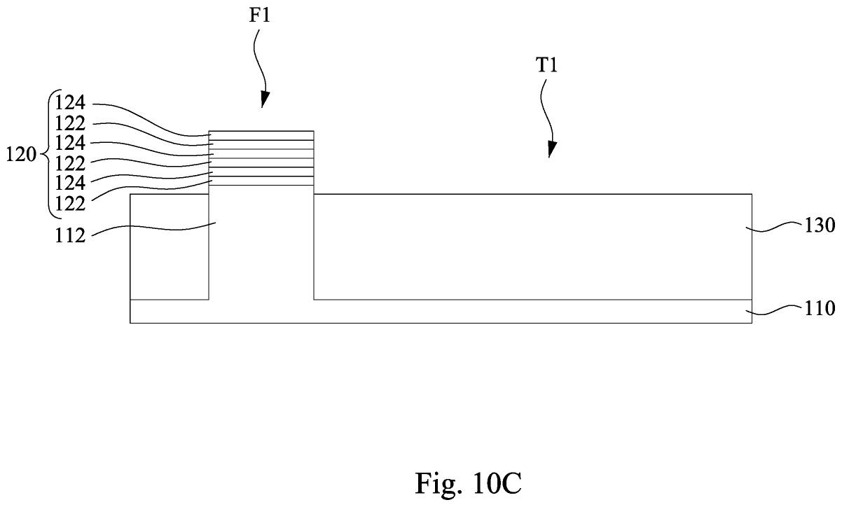

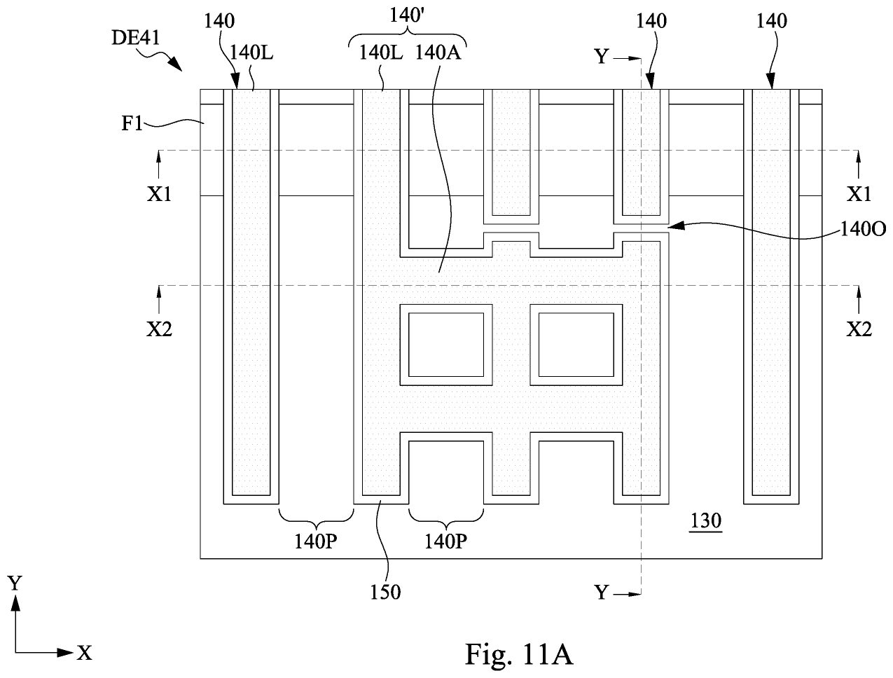

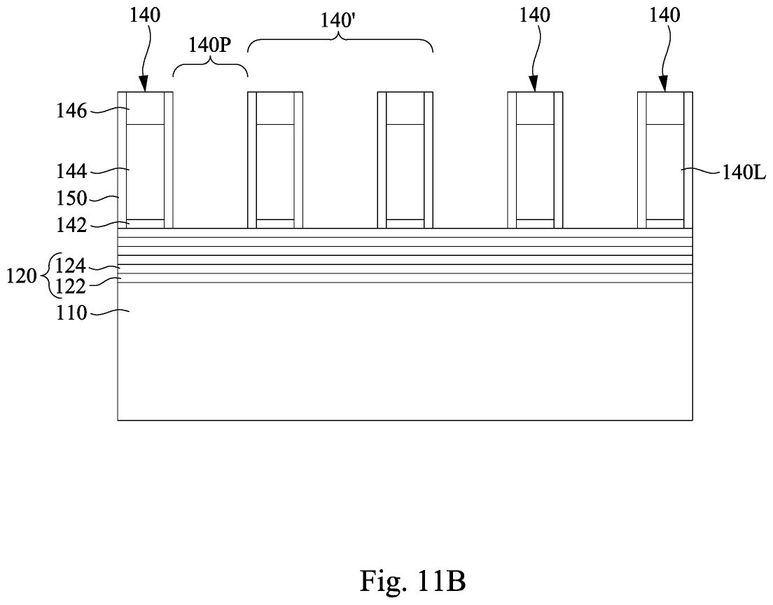

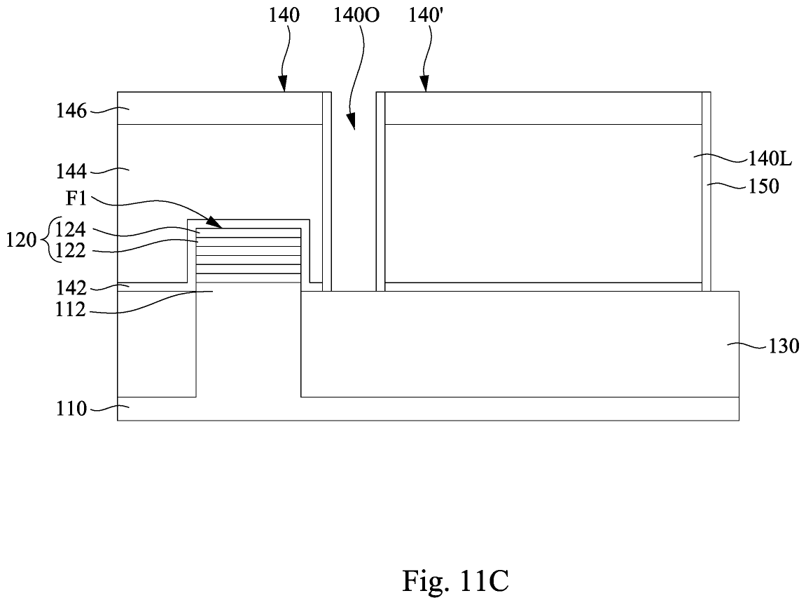

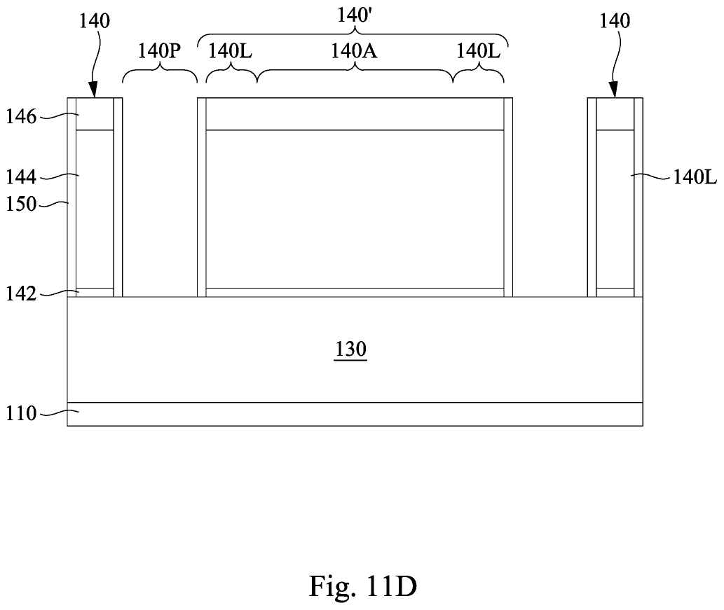

FIG. 9 is a schematic view of an intermediate stage in the fabricating the IC structure DE41 in accordance with some embodiments of the present disclosure. FIGS. 10A, 11A, 12A, 13A, 14A, and 15A are top views of intermediate stages in the fabricating the IC structure DE41 in accordance with some embodiments of the present disclosure. FIGS. 10B, 11B, 12B, 13B, 14B, and 15B are cross-sectional views of intermediate stages of fabricating the IC structure DE41 along a cut X1-X1 (referring to FIGS. 10A, 11A, 12A, 13A, 14A, and 15A). FIGS. 10C, 11C, 13C, 14C, and 15C are cross-sectional views of intermediate stages of fabricating the IC structure DE41 along a cut Y-Y (referring to FIGS. 10A, 11A, 13A, 14A, and 15A). FIGS. 11D, 13D, 14D, and 15D are cross-sectional views of intermediate stages of fabricating the IC structure DE41 along a cut X2-X2 (referring to FIGS. 11A, 13A, 14A, and 15A).

Reference is made to FIG. 9. An epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120 includes epitaxial layers 122 of a first composition interposed by epitaxial layers 124 of a second composition. The first and second compositions can be different. In some embodiments, the epitaxial layers 122 are SiGe and the epitaxial layers 124 are silicon (Si). However, other embodiments are possible including those that provide for a first composition and a second composition having different oxidation rates and/or etch selectivity. In some embodiments, the epitaxial layers 122 include SiGe and where the epitaxial layers 124 include Si, the Si oxidation rate of the epitaxial layers 124 is less than the SiGe oxidation rate of the epitaxial layers 122.

The epitaxial layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. It is noted that three layers of the epitaxial layers 122 and three layers of the epitaxial layers 124 are alternately arranged as illustrated in FIGS. 10B and 10C, which is for illustrative purposes only and not intended to be limiting beyond what is specifically recited in the claims. It can be appreciated that any number of epitaxial layers can be formed in the epitaxial stack 120; the number of layers depending on the desired number of channels regions for the transistor. In some embodiments, the number of epitaxial layers 124 is between 2 and 10.

The epitaxial layers 122 in channel regions(s) may eventually be removed and serve to define a vertical distance between adjacent channel region(s) for a subsequently-formed multi-gate device. Accordingly, the epitaxial layers 122 may also be referred to as sacrificial layers, and epitaxial layers 124 may also be referred to as channel layers.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 324 include the same material as the substrate 110. In some embodiments, the epitaxially grown layers 122 and 124 include a different material than the substrate 110. As stated above, in at least some examples, the epitaxial layers 122 include an epitaxially grown silicon germanium (SiGe) layer and the epitaxial layers 124 include an epitaxially grown silicon (Si) layer. Alternatively, in some embodiments, either of the epitaxial layers 122 and 124 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 122 and 124 may be chosen based on providing differing oxidation and/or etching selectivity properties. In some embodiments, the epitaxial layers 122 and 124 are substantially dopant-free (i.e., having an extrinsic dopant concentration from about 0 cm⁻³ to about 1×10¹⁸ cm⁻³), where for example, no intentional doping is performed during the epitaxial growth process.

Reference is made to FIGS. 10A-10C. A plurality of semiconductor fins F1 extending from the substrate 110 are formed. In various embodiments, each of the fins F1 includes a substrate portion 112 formed from the substrate 110 and portions of each of the epitaxial layers of the epitaxial stack 120 including epitaxial layers 122 and 124. The fins F1 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins F1 by etching initial epitaxial stack 120. The etching process can include dry etching, wet etching, reactive ion etching (RIE), and/or other suitable processes.

As illustrated in FIG. 9, a hard mask (HM) layer 910 is formed over the epitaxial stack 120 prior to patterning the fins F1. In some embodiments, the HM layer 910 includes an oxide layer (e.g., a pad oxide layer that may include SiO₂) and a nitride layer (e.g., a pad nitride layer that may include Si₃N₄) formed over the oxide layer. The oxide layer may act as an adhesion layer between the epitaxial stack 120 and the nitride layer and may act as an etch stop layer for etching the nitride layer. In some examples, the HM oxide layer includes thermally grown oxide, chemical vapor deposition (CVD)-deposited oxide, and/or atomic layer deposition (ALD)-deposited oxide. In some embodiments, the HM nitride layer is deposited on the HM oxide layer by CVD and/or other suitable techniques.

The fins F1 may subsequently be fabricated using suitable processes including photolithography and etch processes. The photolithography process may include forming a photoresist layer (not shown) over the HM layer 910, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process using light in EUV region, having a wavelength of, for example, about 1-100 nm. The patterned mask may then be used to protect regions of the substrate 110, and layers formed thereupon, while an etch process forms trenches T1 in unprotected regions through the HM layer 910, through the epitaxial stack 120, and into the substrate 110, thereby leaving the plurality of extending fins F1. The trenches T1 may be etched using a dry etch (e.g., reactive ion etching), a wet etch, and/or combination thereof. The photoresist layer may be removed by suitable stripping process after the etching processes.

Shallow trench isolation (STI) structures 130 are formed over the substrate 110 and defines active regions. In the present embodiments for forming GAA transistor, the isolation structures 130 are interposing the fins F1, and the active regions by the isolation structures 130 are fins F1 having the epitaxial stack 120. In some alternative embodiments for forming Fin Field-Effect Transistor (FinFet), the active regions defined by the isolation (STI) structures 130 may be fins F1 comprising a single semiconductor material. In some other embodiments for forming planar devices, the active regions defined by the isolation (STI) structures 130 may be regions of the substrate 110 not protruding from a top surface of the substrate 110.

By way of example and not limitation, a dielectric layer is first deposited over the substrate 110, filling the trenches T1 with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, an ALD process, a physical vapor deposition (PVD) process, and/or other suitable process. In some embodiments, the dielectric layer (and subsequently formed STI structures 130) may include a multi-layer structure, for example, having one or more liner layers.

In some embodiments of forming the isolation (STI) structures 130, after deposition of the dielectric layer, the deposited dielectric material is thinned and planarized, for example by a chemical mechanical polishing (CMP) process. In some embodiments, the HM layer 910 (as illustrated FIG. 9) functions as a CMP stop layer. The STI structures 130 interposing the fins F1 are recessed. The STI structures 130 are recessed providing the fins F1 extending above the STI structures 130. In some embodiments, the recessing process may include a dry etching process, a wet etching process, and/or a combination thereof. The HM layer 910 (as illustrated FIG. 9) may also be removed before, during, and/or after the recessing of the STI structures 130. The nitride layer of the HM layer 910 (as illustrated FIG. 9) may be removed, for example, by a wet etching process using H₃PO₄ or other suitable etchants. In some embodiments, the oxide layer of the HM layer 910 (as illustrated FIG. 9) is removed by the same etchant used to recess the STI structures 130. In some embodiments, a recessing depth is controlled (e.g., by controlling an etching time) so as to result in a desired height of the exposed upper portion of the fins F1. In the illustrated embodiments, the desired height exposes each of the layers of the epitaxial stack 120 in the fins F1.

Reference is made to FIGS. 11A-11D. Plural gate structures 140 and 140′ are formed over the substrate 110. In some embodiments, the gate structures 140 and 140′ are dummy (sacrificial) gate structures that are subsequently removed. Thus, in some embodiments using a gate-last process, the gate structures 140 and 140′ are dummy gate structures and will be replaced by the final gate structures at a subsequent processing stage of the semiconductor device. In particular, the dummy gate structures 140 and 140′ may be replaced at a later processing stage by a high-k dielectric layer (HK) and metal gate electrode (MG) as discussed below.

Each of the dummy gate structures 140 and 140′ may include gate lines 140L extending along substantially parallel to each other, for example, substantially long a direction Y. Every two adjacent gate lines 140L are spaced from each other, for example, by a gate line space 140P. In the present embodiments, each of the gate lines 140L is at least partially over the fins F1, for example, extending across the fins F1. Portions of the fins F1 underlying the gate lines 140L may be referred to as the channel regions. The gate lines 140L may also define a source/drain (S/D) region of the fins F1, for example, the regions of the fin F1 adjacent and on opposing sides of the channel region. In some other embodiments, some of the gate lines 140L are at least partially over the fins F1, and the other of the gate lines 140L are entirely over the STI structures 130 and free of overlapping the fins F1.

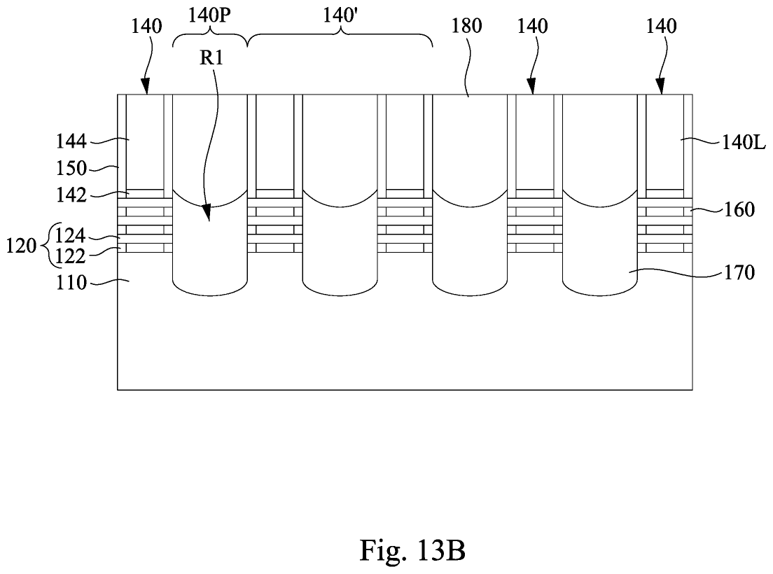

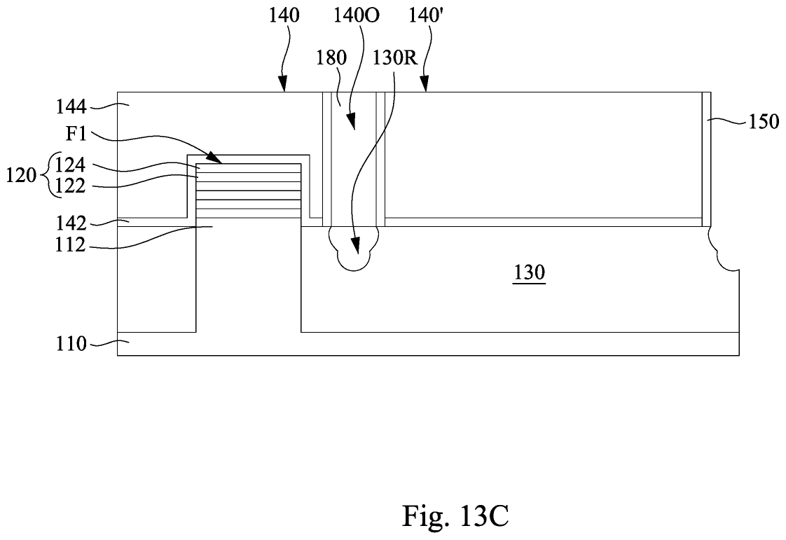

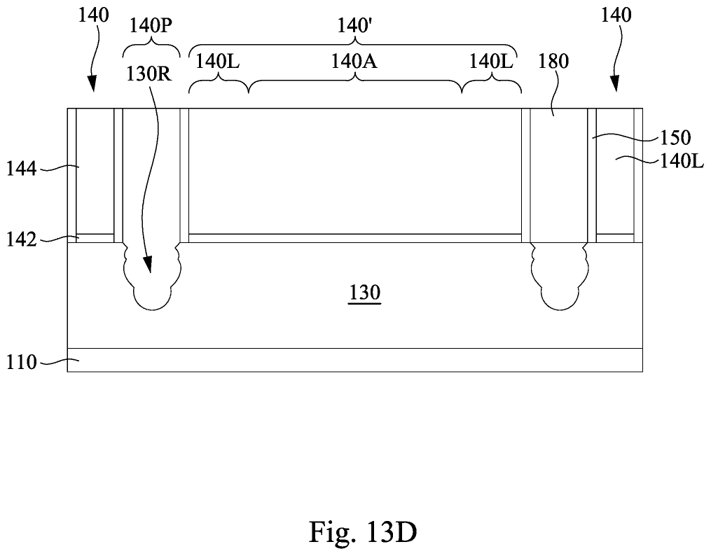

In a process of fabricating a semiconductor device, one or more wet chemical process during the fabrication process may consume oxides in the STI structures 130, resulting poly line collapse easily. For example, the wet chemical process may include one or more etching and/or cleaning processes (e.g., using HF, diluted water, or the like). One of the etching processes may be performed during the source/drain formation as illustrated in FIGS. 13A-13D later.

In some embodiments of the present disclosure, the dummy gate structures 140′ include auxiliary gate portions 140A extending from a sidewall of one gate line 140L to a sidewall of another gate line 140L along a direction X perpendicular to the direction Y, thereby connect two or more gate lines 140L. Stated differently, the auxiliary gate portions 140A may extend through plural gate lines 140L from the top view of FIG. 11A. Through the configuration, the auxiliary gate portions 140A provide structural support between the gate lines 140L, thereby avoiding poly collapse. In the context, the dummy gate structures with the auxiliary gate portions 140A are referred to as the dummy gate structure 140′, and the dummy gate structures without the auxiliary gate portions 140A are referred to as the dummy gate structure 140.

In some embodiments, the gate structure 140′ (i.e., a combination of the gate lines 140L and the auxiliary gate portions 140A) may be an active or operative gate structure, and for example, may overlap the fin F1. In some embodiments, for avoiding shorting gates of transistors, when the gate structure 140′ is an active or operative gate structure, one of the gate lines 140L of the gate structure 140′ may overlap the fin F1, and the others of the gate lines 140L of the gate structure 140′ may not overlap the fin F1. In some alternative embodiments, when gates of two transistors are designed to be electrically connected to each other and isolated from other transistors, the gate lines 140L of the said two gate structure 140′ may overlap the fin F1, and the other of the gate lines 140L of the gate structure 140′ may not overlap the fin F1. In some other embodiments, the gate structure 140′ (i.e., a combination of the gate lines 140L and the auxiliary gate portions 140A) may be an inactive or non-operative gate structure, and may not overlap the fin F1 from the top view. For example, an entirety of the inactive or non-operative gate structure 140′ may be over the STI structures 130.

In some embodiments, the gate structure 140 (i.e., the gate line 140L) may be an active or operative gate structure, and for example, may overlap the fin F1. In some other embodiments, the gate structure 140 (i.e., the gate line 140L) may be an inactive or non-operative gate structure, and may not overlap the fin F1 from the top view. For example, an entirety of the inactive or non-operative gate structure 140 may be over the STI structures 130.

In the illustrated embodiments, the formation of the gate structures 140 and 140′ first forms a dummy gate dielectric layer 142 over the fins F1. In some embodiments, the dummy gate dielectric layer 142 may include SiO₂, silicon nitride, a high-k dielectric material and/or other suitable material. In various examples, the dummy gate dielectric layer 142 may be deposited by a CVD process, a subatmospheric CVD (SACVD) process, a flowable CVD process, an ALD process, a PVD process, or other suitable process. By way of example, the dummy gate dielectric layer 142 may be used to prevent damages to the fins F1 by subsequent processes (e.g., subsequent formation of the dummy gate structures). Subsequently, the formation of the gate structures 140 and 140′ forms a dummy gate electrode layer 144 and a hard mask 146 which may include multiple layers (e.g., an oxide layer and a nitride layer). In some embodiments, the dummy gate structures 140 and 140′ are formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof.

In forming the gate structure for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the lithography process uses the gate layout pattern GP and the cut-gate layout patterns OG1 and OG2 in the layout L4 of FIG. 8 to define a pattern of the photoresist. The hard mask 146 and the dummy gate electrode layer 144 are then patterned by one or more etching processes. The etching process(es) may remove portions of the hard mask 146 and the dummy gate electrode layer 144 unprotected by the patterned photoresist, and remain other portions the hard mask 146 and the dummy gate electrode layer 144 protected by the patterned photoresist. In some embodiments, the etching process may include dry etching (e.g., RIE etching), wet etching, and/or other etching methods. In some embodiments, the dummy gate electrode layer 144 may include polycrystalline silicon (polysilicon). In some embodiments, the hard mask 146 includes an oxide layer such as a pad oxide layer that may include SiO₂, and a nitride layer such as a pad nitride layer that may include Si₃N₄.

In some embodiments, after patterning the hard mask 146 and the dummy gate electrode layer 144, the dummy gate dielectric layer 142 may be removed from the S/D regions of the fins F1. The etch process may include a wet etch, a dry etch, and/or a combination thereof. The etch process is chosen to selectively etch the dummy gate dielectric layer 142 without substantially etching the fins F1, the dummy gate electrode layer 144, and the hard mask 146. Due to etch loading, the hard mask 146 of the gate structure 140′ including the auxiliary gate portions 140A may have a higher top surface than a top surface of the hard mask 146 of the gate structure 140 as shown in FIG. 11D.

After the patterning process and the etching processes, for avoiding transistor shorting, a gate line 140L of the gate structure 140′ free of overlapping the fins F1 is aligned to and separated apart from a gate line 140L of the gate structure 140 across the fins F1 along the Y direction. For example, the gate opening 1400 spaces the gate line 140L of the gate structure 140′ free of overlapping the fins F1 from the gate line 140L of the gate structure 140 across the fins F1 along the Y direction.

After the formation of the dummy gate structures 140 and 140′, gate spacers 150 are formed on sidewalls of the dummy gate structures 140 and 140′. For example, a spacer material layer is conformally deposited on the substrate using processes such as, CVD process, a subatmospheric CVD (SACVD) process, a flowable CVD process, an ALD process, a PVD process, or other suitable process. The spacer material layer may include a dielectric material such as silicon oxide, silicon nitride, silicon carbide, silicon oxynitride, SiCN films, silicon oxycarbide, SiOCN films, and/or combinations thereof. The spacer material layer is subsequently etched back to form the gate spacers 150. For example, an anisotropic etching process is performed on the deposited spacer material layer to expose portions of the fins F1 not covered by the dummy gate structures 140 and 140′ (e.g., in source/drain regions of the fins F1). Portions of the spacer material layer directly above the dummy gate structures 140 and 140′ may be completely removed by this anisotropic etching process. In some embodiments, the spacer material layer includes multiple layers, and therefore the gate spacers 150 may be multi-layer structures.

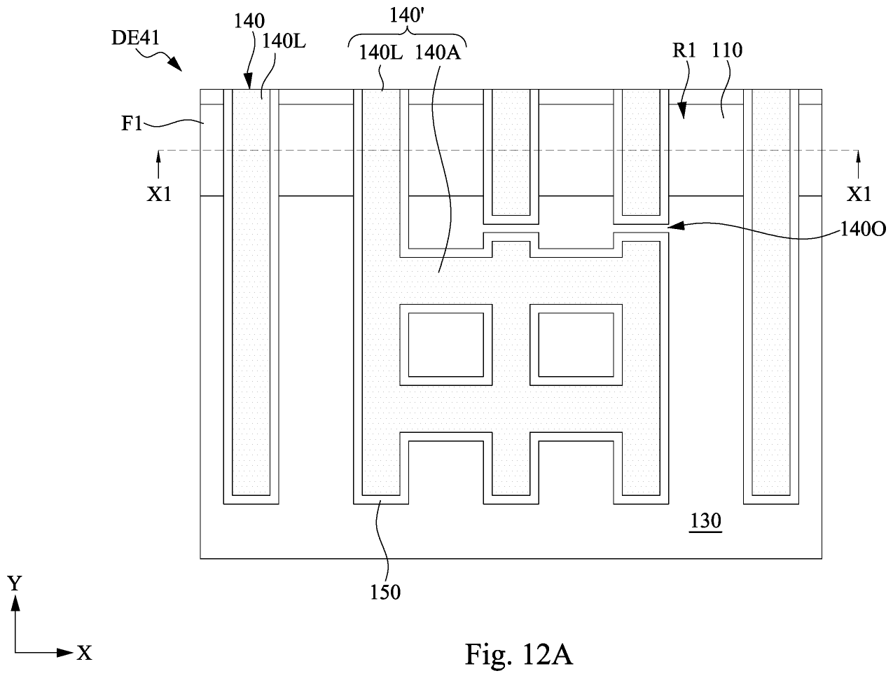

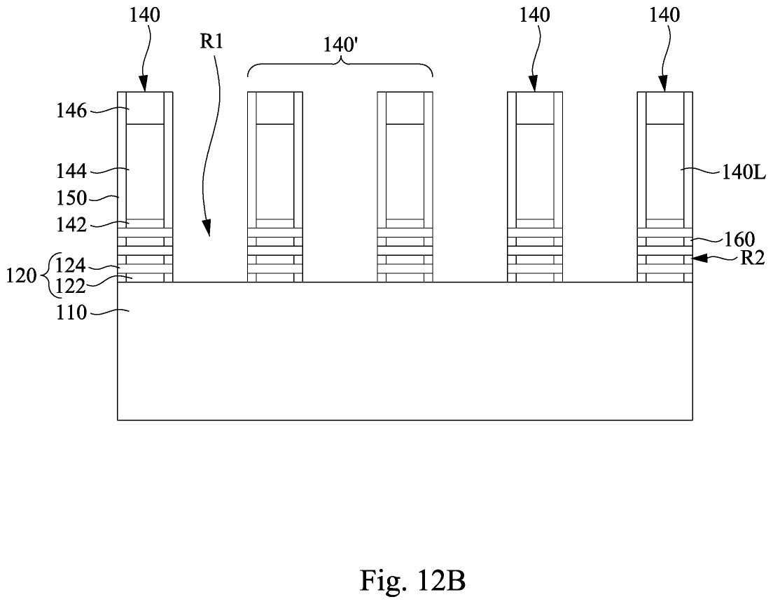

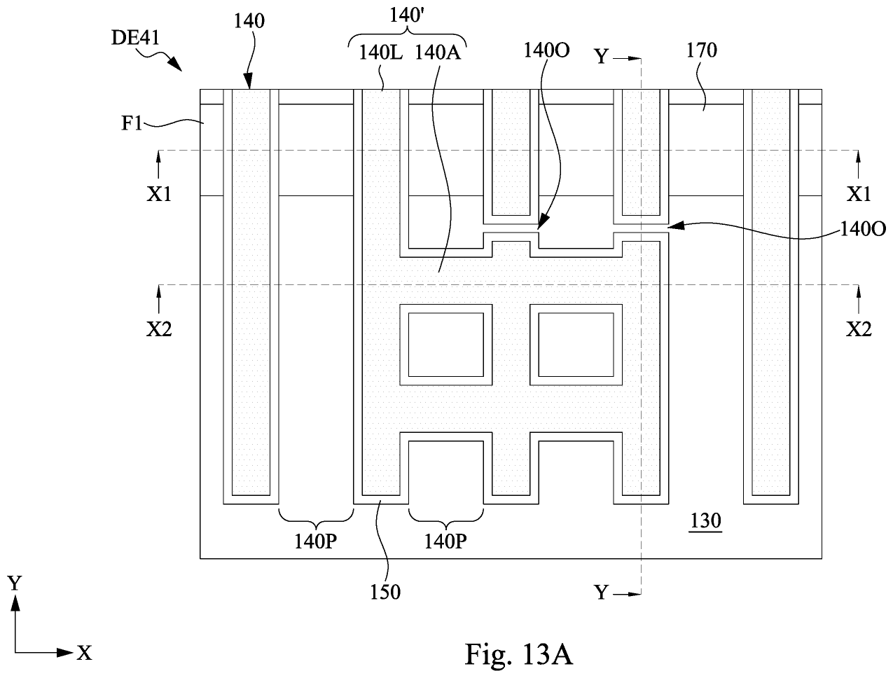

Reference is made to FIGS. 12A and 12B. Exposed portions of the semiconductor fins F1 that extend laterally beyond sidewalls of the gate spacers 150 (e.g., in source/drain regions of the fins F1) are etched by using, for example, an anisotropic etching process that uses the dummy gate structure 140 and 140′ and the gate spacers 150 as an etch mask, resulting in recesses R1 into the semiconductor fins F1 and between corresponding dummy gate lines 140L. After the anisotropic etching, end surfaces of the sacrificial layers 122 and channel layers 124 are aligned with respective outermost sidewalls of the gate spacers 150, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

The, end surfaces of the sacrificial layers 122 are laterally or horizontally recessed by using suitable selective etching process, resulting in lateral recesses R2 each vertically between corresponding channel layers 124. By way of example and not limitation, the sacrificial layers 122 are SiGe and the channel layers 124 are silicon allowing for the selective etching of the sacrificial layers 122. In some embodiments, the selective wet etching includes an APM etch (e.g., ammonia hydroxide-hydrogen peroxide-water mixture) that etches SiGe at a faster etch rate than it etches Si. In some embodiments, the selective etching includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower than oxidation rate of SiGe, the channel layers 124 is not significantly etched by the process of laterally recessing the sacrificial layers 122. As a result, the channel layers 124 laterally extend past opposite end surfaces of the sacrificial layers 122.

Inner spacers 160 are subsequently formed on opposite end surfaces of the laterally recessed sacrificial layers 122. In some embodiments, an inner spacer material layer is formed to fill the recesses R2. The inner spacer material layer may be a low-K dielectric material, such as SiO₂, SiN, SiCN, or SiOCN, and may be formed by a suitable deposition method, such as ALD. After the deposition of the inner spacer material layer, an anisotropic etching process may be performed to trim the deposited inner spacer material, such that only portions of the deposited inner spacer material that fill the recesses R2 left by the lateral etching of the sacrificial layers 122 are left. After the trimming process, the remaining portions of the deposited inner spacer material are denoted as inner spacers 160. The inner spacers 160 serve to isolate metal gates from source/drain regions formed in subsequent processing. In the example of FIGS. 6A and 6B, sidewalls of the inner spacers 160 are aligned with sidewalls of the channel layers 124.

Reference is made to FIGS. 13A-13D. Source/drain epitaxial structures 170 are formed in the recesses R1 in the fins F1. The source/drain epitaxial structures 170 may be formed by performing an epitaxial growth process that provides an epitaxial material on the fins F1. During the epitaxial growth process, the dummy gate structures 140, 140′, and gate spacers 150 limit the source/drain epitaxial structures 170 to the source/drain regions. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the fins F1 and the channel layers 124.

In some embodiments, the source/drain epitaxial structures 170 may include Ge, Si, GaAs, AlGaAs, SiGe, GaAsP, SiP, or other suitable material. The source/drain epitaxial structures 290S/290D may be in-situ doped during the epitaxial process by introducing doping species including: p-type dopants, such as boron; n-type dopants, such as phosphorus or arsenic; and/or other suitable dopants including combinations thereof. If the source/drain epitaxial structures 170 are not in-situ doped, an implantation process (i.e., a junction implant process) is performed to dope the source/drain epitaxial structures 170. In some exemplary embodiments, the source/drain epitaxial structures 170 in an NFET device include SiP, while those in a PFET device include GeSnB and/or SiGeSnB.

In some embodiments, the formation of the recess R1 and R2 (referring to FIGS. 12A and 12B) and the formation of the source/drain epitaxial structures 170 (referring to FIGS. 13A-13D) includes plural etching processes and cleaning processes, which may consume oxides of the STI structures 130. For example, the STI structures 130 being consumed may have the recesses 130R in the exposed region. The recesses 130R may lateral extend to a position directly below the gate spacers 150, sometimes may to a position directly below the gate lines 140L. In absence of the auxiliary gate portions 140A, the recesses 130R may be wider and deeper. As the devices size shrinks (for example a width of the gate lines GL becomes less than about 20 nanometers), the poly line (e.g., the gate lines 140L) may collapse due to the oxide consume on the poly lines.

In some embodiments of the present disclosure, by using the auxiliary gate portions 140A providing structural support between the gate lines 140L, the stability of the poly lines is improved. Also, since the configuration of the auxiliary gate portions 140A limit the exposed region of STI structures 130, the etching processes and cleaning processes may not serious consume the STI structures 130. Through the configuration of the auxiliary gate portions 140A, poly line collapse can be avoided.

After the formation of source/drain epitaxial structures 170, an interlayer dielectric (ILD) layer 180 is deposited over the substrate 110 and filling the spaces between the dummy gate structures 140 and/or 140′ (e.g., the gate line spaces 140P and the gate openings 1400). The ILD layer 180 may also fill the recesses 130R in the STI structures 130. In some embodiments, the ILD layer 180 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 180 may be deposited by a PECVD process or other suitable deposition technique. In some embodiments, a high thermal budget process may be performed to anneal the ILD layer 180. In some embodiments, a contact etch stop layer (CESL) may be formed in the space between the dummy gate structures 140 prior to the deposition of the ILD layer 180. In some examples, the CESL includes a silicon nitride layer, silicon oxide layer, a silicon oxynitride layer, and/or other suitable materials having a different etch selectivity than the ILD layer 180. The CESL may be formed by plasma-enhanced chemical vapor deposition (PECVD) process and/or other suitable deposition or oxidation processes.

After depositing the ILD layer 180, a planarization process may be performed to remove excessive materials of the ILD layer 180. For example, a planarization process includes a chemical mechanical planarization (CMP) process which removes portions of the ILD layer 180 and the CESL layer overlying the dummy gate structures 140 and 140′ and planarizes a top surface of the IC structure. In some embodiments, the CMP process also removes the hard mask 146 in the dummy gate structures 140 and/or 140′ (as shown in FIG. 12B) and exposes the dummy gate electrode layer 144.

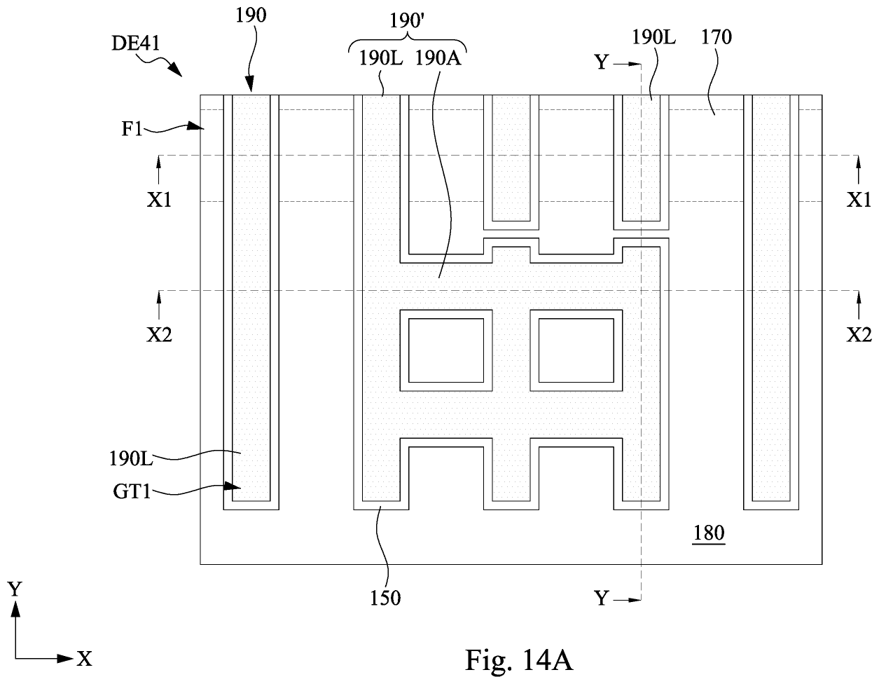

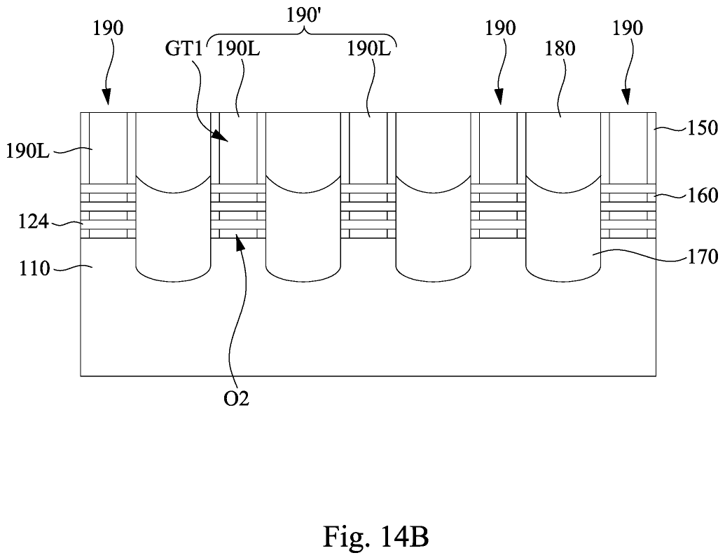

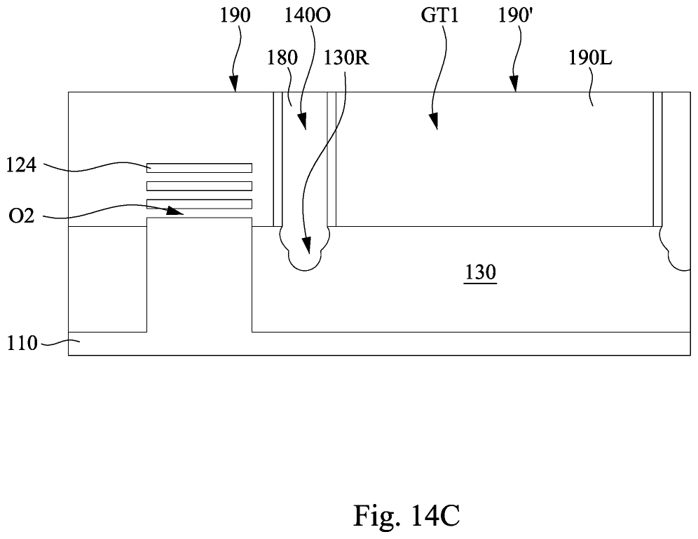

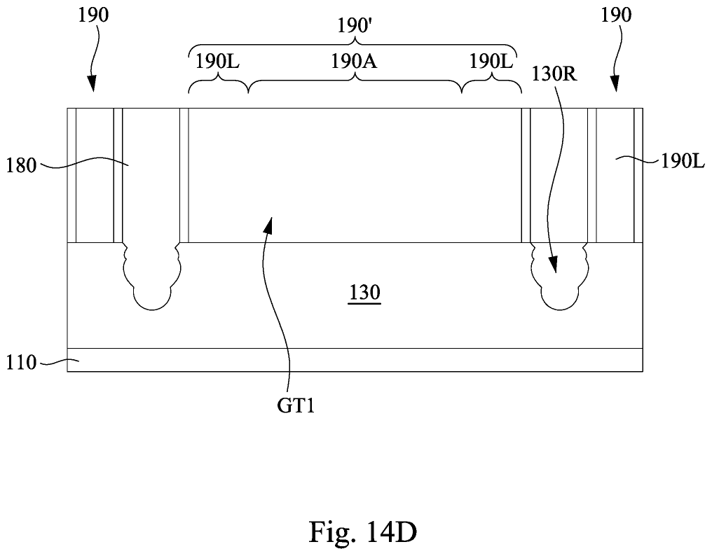

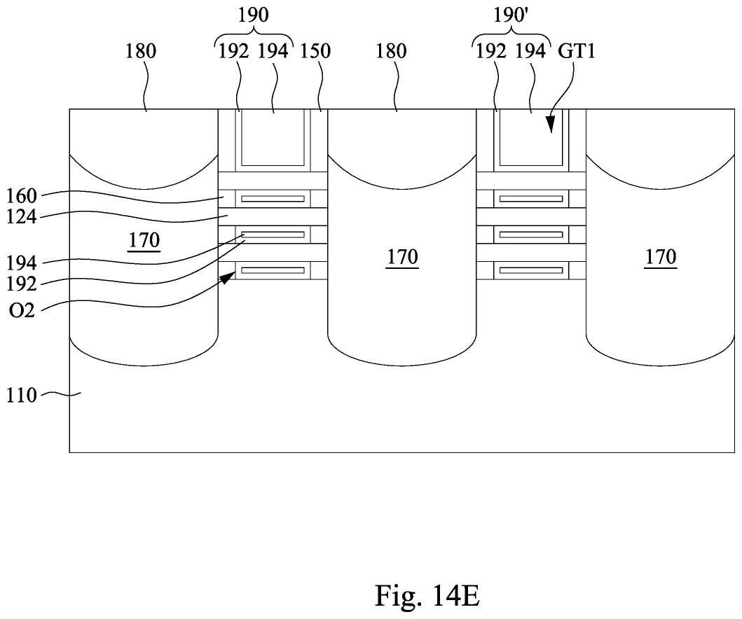

Reference is made to FIGS. 14A-14D. A gate replacement process is performed to replace the dummy gate structures 140 and 140′ and the sacrificial layers 122 (referring to FIGS. 13A-13D) with high-k/metal gate structures. The dummy gate structures 140 and 140′ (referring to FIGS. 13A-13D) are removed, followed by removing the sacrificial layers 122 (referring to FIGS. 13A-13D). In the illustrated embodiments, the dummy gate structures 140 and 140′ (referring to FIGS. 13A-13D) are removed by using a selective etching process (e.g., selective dry etching, selective wet etching, or a combination thereof) that etches the materials in dummy gate structures 140 and 140′ (referring to FIGS. 13A-13D) at a faster etch rate than it etches other materials (e.g., gate spacers 150, CESL, and/or ILD layer 180), thus resulting in gate trenches GT1 between corresponding gate spacers 150, with the sacrificial layers 122 (referring to FIGS. 13A-13D) exposed in the gate trenches GT1. Subsequently, the sacrificial layers 122 (referring to FIGS. 13A-13D) in the gate trenches GT1 are etched by using another selective etching process that etches the sacrificial layers 122 at a faster etch rate than it etches the channel layers 124, thus forming openings/spaces O2 between neighboring channel layers 124. In this way, the channel layers 124 become nanosheets suspended over the substrate 110 and between the source/drain epitaxial structures 170. This step is also called a channel release process. At this interim processing step, the openings O2 between nanosheets 124 may be filled with ambient environment conditions (e.g., air, nitrogen, etc). In some embodiments, the nanosheets 124 can be interchangeably referred to as nanowires, nanoslabs and nanorings, depending on their geometry. For example, in some other embodiments the channel layers 124 may be trimmed to have a substantial rounded shape (i.e., cylindrical) due to the selective etching process for completely removing the sacrificial layers 122 (referring to FIGS. 13A-13D). In that case, the resultant channel layers 124 can be called nanowires.

In some embodiments, the sacrificial layers 122 (referring to FIGS. 13A-13D) are removed by using a selective wet etching process. In some embodiments, the sacrificial layers 122 (referring to FIGS. 13A-13D) are SiGe and the channel layers 124 are silicon allowing for the selective removal of the sacrificial layers 122 (referring to FIGS. 13A-13D). In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the channel layers 124 may remain substantially intact during the channel release process. In some embodiments, both the channel release step and the previous step of laterally recessing sacrificial layers use a selective etching process that etches SiGe at a faster etch rate than etching Si, and therefore these two steps may use the same etchant chemistry in some embodiments. In this case, the etching time/duration of channel release step is longer than the etching time/duration of the previous step of laterally recessing sacrificial layers, so as to completely remove the sacrificial SiGe layers.

Replacement gate structures 190 and 190′ are respectively formed in the gate trenches GT1 to surround each of the nanosheets 124 suspended in the gate trenches GT1. The gate structures 190 and 190′ may be final gates of GAA FETs. The final gate structure may be a high-k/metal gate stack, however other compositions are possible. In some embodiments, each of the gate structures 190 and 190′ forms the gate associated with the multi-channels provided by the plurality of nanosheets 124. For example, high-k/metal gate structures 190 and 190′ are formed within the openings O2 provided by the release of nanosheets 124.

FIG. 14E illustrated an enlarge view of a portion of FIG. 14B. Reference is made to FIGS. 14A-14E. In various embodiments, each of the high-k/metal gate structures 190 and 190′ includes a gate dielectric layer 192 formed around the nanosheets 124 and a gate metal layer 194 formed around the dielectric layer 192 and filling a remainder of gate trenches GT1. Formation of the high-k/metal gate structures 190 and 190′ may include one or more deposition processes to form various gate materials, followed by a CMP processes to remove excessive gate materials, resulting in the high-k/metal gate structures 190 and 190′ having top surfaces level with a top surface of the ILD layer 180. Thus, transistors (e.g., GAA FET) are formed, and the high-k/metal gate structures 190 and 190′ surrounds each of the nanosheets 124, and thus is referred to as a gate of the transistors (e.g., GAA FET).

The gate dielectric layer 192 may include an interfacial layer and a high-k gate dielectric layer over the interfacial layer. In some embodiments, the interfacial layer is silicon oxide formed on exposed surfaces of semiconductor materials in the gate trenches GT1 by using, for example, thermal oxidation, chemical oxidation, wet oxidation or the like. As a result, surface portions of the nanosheets 124 and the substrate 110 exposed in the gate trenches GT1 are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 194 includes one or more metal layers. For example, the gate metal layer 194 may include one or more work function metal layers stacked one over another and a fill metal filling up a remainder of gate trenches GT1. The one or more work function metal layers in the gate metal layer 194 provide a suitable work function for the high-k/metal gate structures 310. For an n-type GAA FET, the gate metal layer 194 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the gate metal layer 194 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 194 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

The high-k/metal gate structures 190 and 190′ may include gate lines 190L, and the high-k/metal gate structures 190′ may further includes auxiliary gate portions 190A. The configuration of the gate lines 190L are corresponding to the gate lines 140L in FIGS. 13A-13D, and the configuration of the auxiliary gate portions 190A are corresponding to the auxiliary gate portions 140A in FIGS. 13A-13D. In some embodiments, the high-k/metal gate structures 190 and/or 190′ are active gates, which forms active transistors with the nanosheets 124 and the source/drain epitaxial structures 170. In some other embodiments, the high-k/metal gate structures 190 and/or 190′ are inactive (or non-operative) gates being floating or connected to stable voltage power supplies, in which the high-k/metal gate structures 190 and/or 190′ does not extend across the nanosheets 124. The auxiliary gate portions 190A may extend through plural gate lines 140L from the top view and provide structural support between the gate lines 190L. Other details are similar to those aforementioned, and thereto not repeated herein.

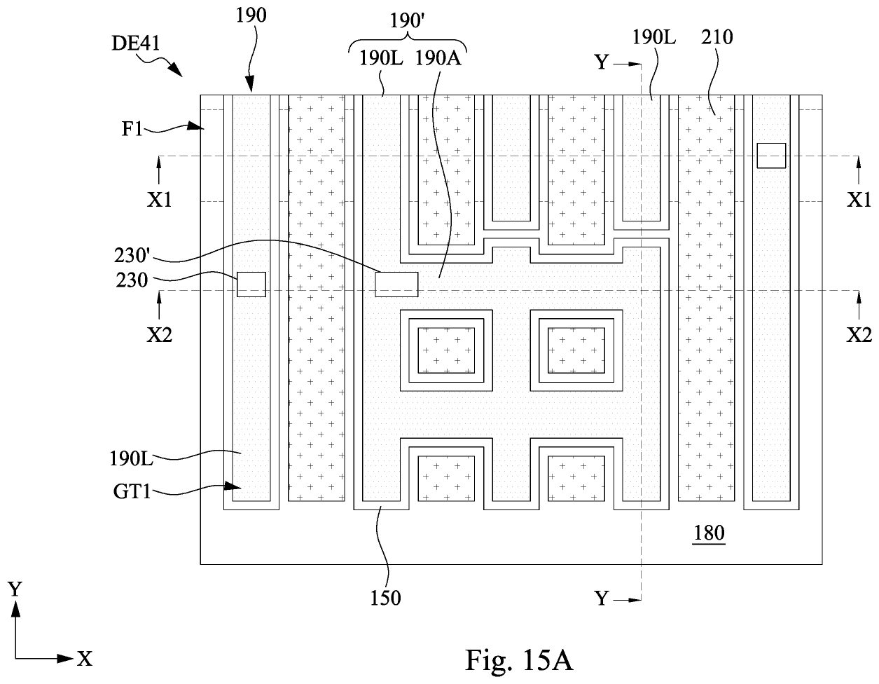

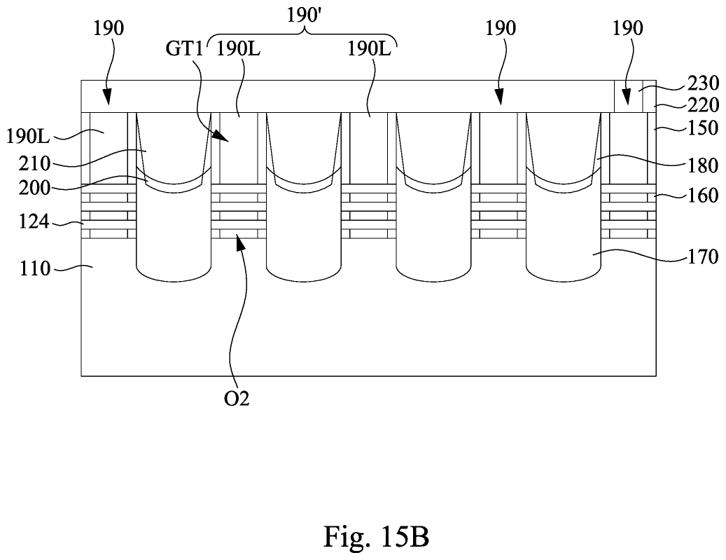

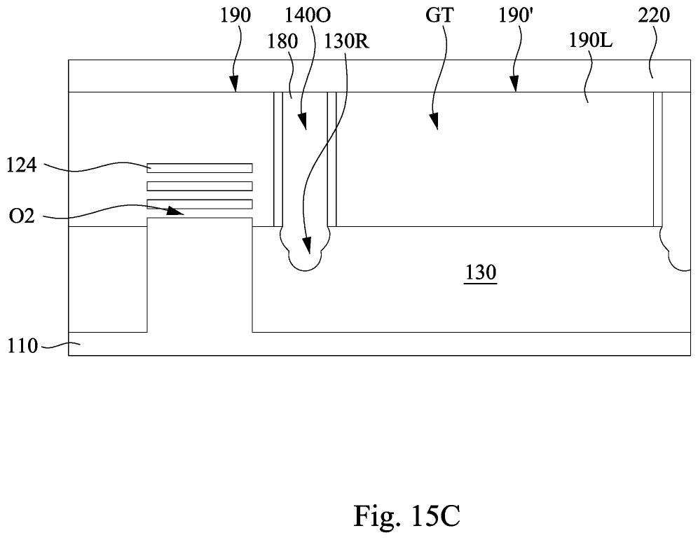

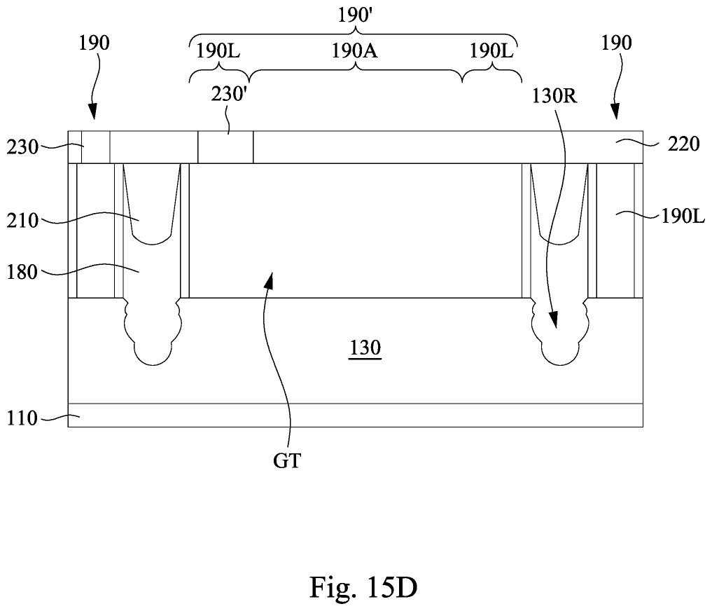

Reference is made to FIGS. 15A-15D. Source/drain contacts 210 are formed over the source/drain epitaxial structure 170. In some embodiments, the source/drain contact formation step comprises etching source/drain contact openings through the ILD layer 180 to expose the source/drain epitaxial structures 170 and depositing one or more metal materials to fill the source/drain contact openings. The metal materials may include W, Ru, Co, Cu, Ti, TiN, Ta, TaN, Mo, Ni, the like or combinations thereof. The metal materials may be deposited by using suitable deposition techniques (e.g., CVD, PVD, ALD, the like or combinations thereof). After the metal deposition, a CMP process is performed to remove excess metal materials outside the source/drain contact openings, while leaving metal materials in the source/drain contact openings to serve as the source/drain contacts 210. In some embodiments, prior to the metal deposition, metal silicide regions 200 may be formed on exposed surfaces of the source/drain epitaxial structures 170 by using a silicidation process. Silicidation may be formed by blanket depositing a metal layer over the exposed source/drain epitaxial structures 170, annealing the metal layer such that the metal layer reacts with silicon (and germanium if present) in the source/drain epitaxial structures 170 to form the metal silicide regions 200, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys.

After the formation of source/drain contacts 210, an ILD layer 220 is deposited over the substrate 110. The ILD layer 220 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 220 may be deposited by a PECVD process or other suitable deposition technique.

Gate contacts 230 and 230′ are formed over the gate structures 190 and 190′, respectively. In some embodiments, the gate contact formation step comprises etching gate contact openings through the ILD layer 220 to expose the gate structures 190 and 190′ and depositing one or more metal materials to fill the gate contact openings. The metal materials may include W, Ru, Co, Cu, Ti, TiN, Ta, TaN, Mo, Ni, the like or combinations thereof. The metal materials may be deposited by using suitable deposition techniques (e.g., CVD, PVD, ALD, the like or combinations thereof). After the metal deposition, a CMP process is performed to remove excess metal materials outside the source/drain contact openings, while leaving metal materials in the source/drain contact openings to serve as the gate contacts 230 and 230′.

In some embodiments of the present disclosure, since the gate structure 190′ comprises the auxiliary gate portions 190A, the gate structure 190′ have a wide region to receive the gate contact 230′. For example, the gate contact 230′ have a first portion over the gate line 190L and a second portion over the auxiliary gate portions 190A. For example, a width of the gate contact 230′ is greater than a width of the gate contact 230 along the direction Y, and/or a length of the gate contact 230′ is greater than a length of the gate contact 230 along the direction Y. The gate structure 190′ has a greater area in contact with the gate contact 230′ than an area of the gate structure 190 in contact with the gate contact 230, thereby reducing resistance.

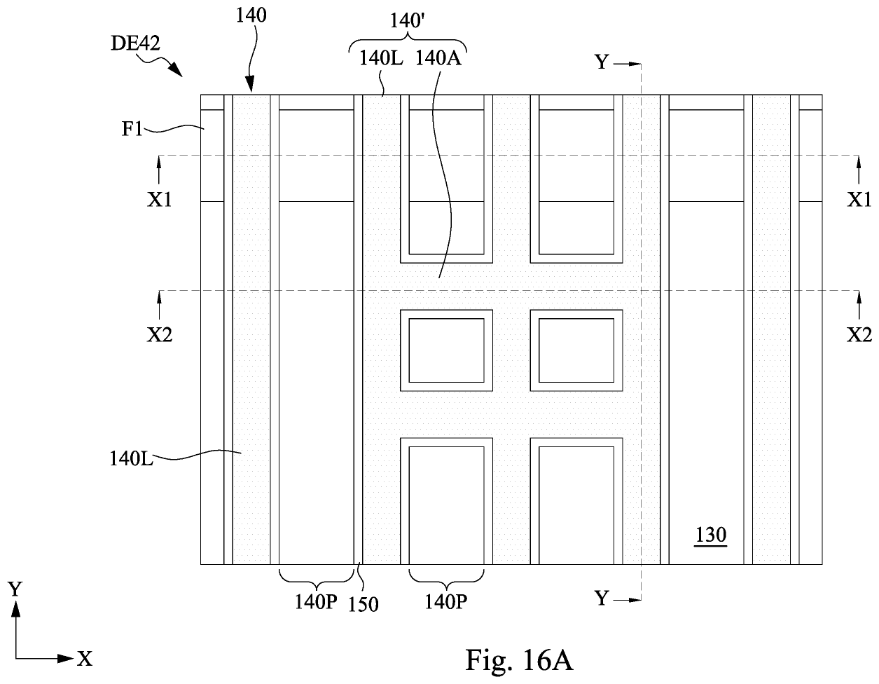

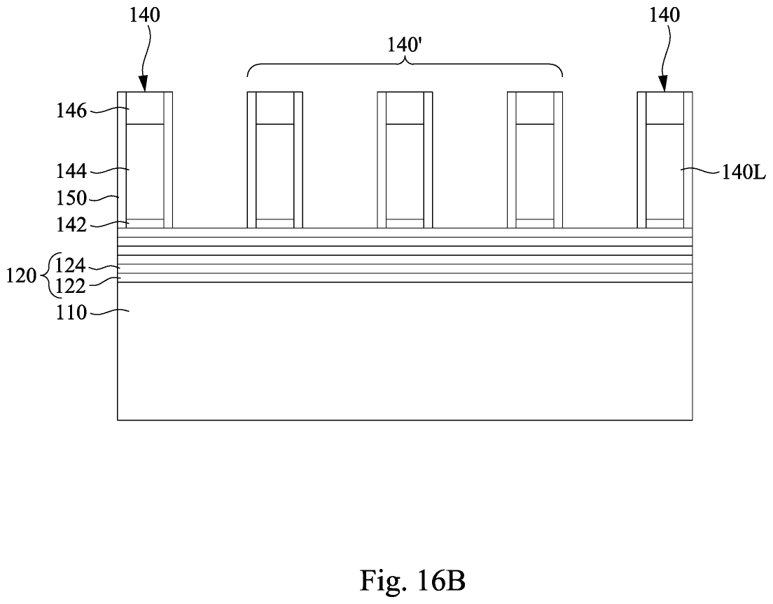

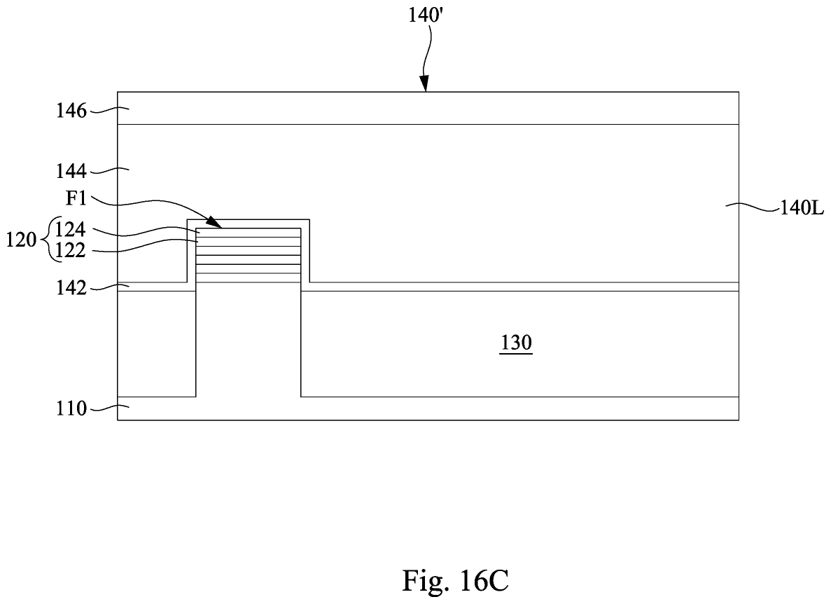

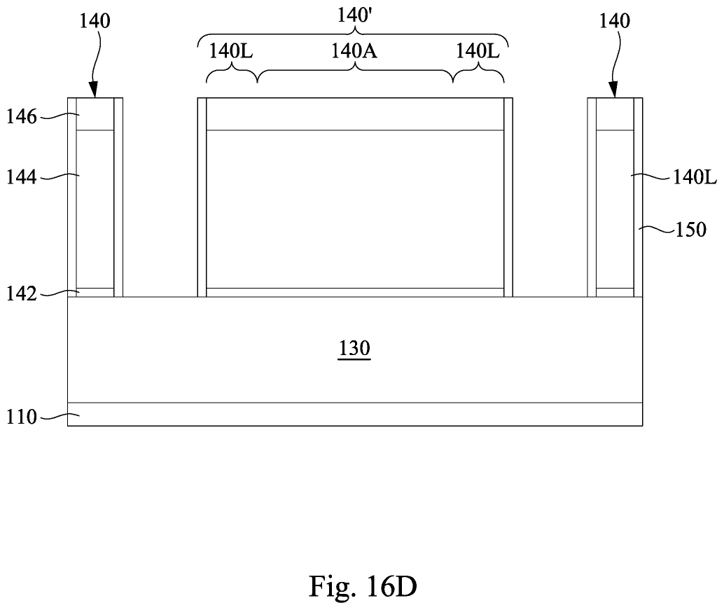

FIGS. 16A-19D illustrate various stages of fabricating an IC structure DE42 using the IC layout L4 of FIG. 8 according to some embodiments of the present disclosure. The IC structure DE42 inherits geometry of those patterns in the layout L4 of FIG. 8. The details of the present embodiments are similar to those illustrated in FIG. 9-15D, except that the gate lines are cut after the formation of the dummy gate structure and prior to the gate replacement process in the present embodiments. It is understood that additional operations may be provided before, during, and after the operations shown by FIGS. 16A-19D, and some of the operations described below can be replaced or eliminated for additional embodiments of the method. The order of the operations/processes may be interchangeable.

FIGS. 16A, 17A, 18A, and 19A are top views of intermediate stages in the fabricating the IC structure DE42 in accordance with some embodiments of the present disclosure. FIGS. 16B, 17B, 18B, and 19B are cross-sectional views of intermediate stages of fabricating the IC structure DE42 along a cut X1-X1 (referring to FIGS. 16A, 17A, 18A, and 19A). FIGS. 16C, 17C, 18C, and 19C are cross-sectional views of intermediate stages of fabricating the IC structure DE42 along a cut Y-Y (referring to FIGS. 16A, 17A, 18A, and 19A). FIGS. 16D, 17D, 18D, and 19D are cross-sectional views of intermediate stages of fabricating the IC structure DE42 along a cut X2-X2 (referring to FIGS. 16A, 17A, 18A, and 19A).

Reference is made to FIGS. 16A-16D. Following the formation of the fins F1 as illustrated in FIGS. 10A-10C, plural dummy (sacrificial) gate structures 140 and 140′ are formed over the substrate 110. The dummy gate structures 140 and 140′ are formed by various process steps such as layer deposition, patterning, etching, as well as other suitable processing steps. The layer deposition includes forming a dummy gate dielectric layer 142 over the fins F1, forming a dummy gate electrode layer 144 over the dummy gate dielectric layer 142, and forming a hard mask 146 over the dummy gate electrode layer 144. The patterning process includes a lithography process (e.g., photolithography or e-beam lithography). In some embodiments, the lithography process uses the gate layout pattern GP in the layout L4 of FIG. 8 to define a pattern of photoresist. The hard mask 146 and the dummy gate electrode layer 144 are then patterned by one or more etching processes. The etching process(es) may remove portions of the hard mask 146 and the dummy gate electrode layer 144 unprotected by the patterned photoresist, and remain other portions the hard mask 146 and the dummy gate electrode layer 144 protected by the patterned photoresist. After the patterning process and the etching process, the gate lines 140L are overlapping the fins F1.

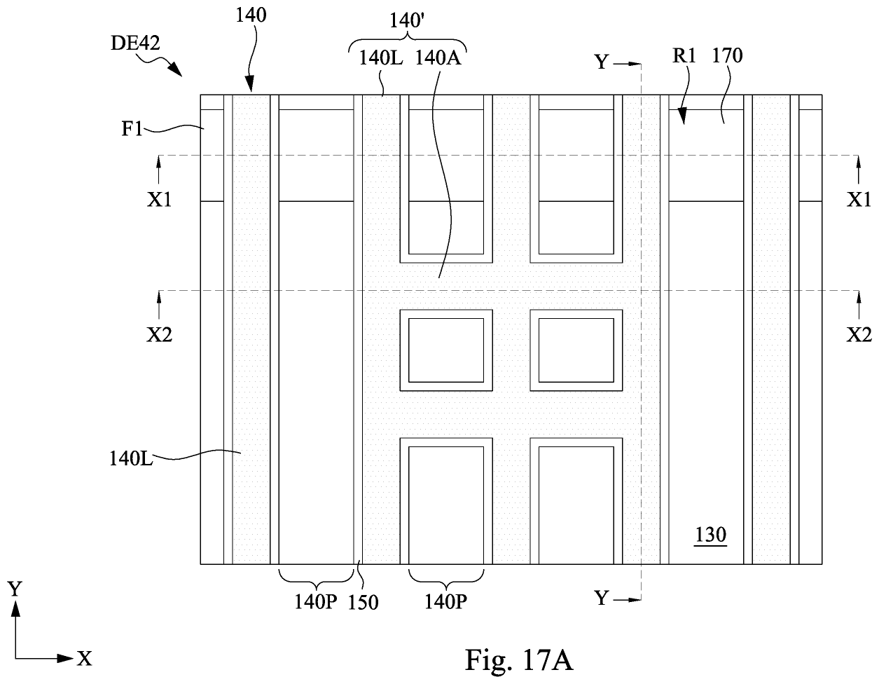

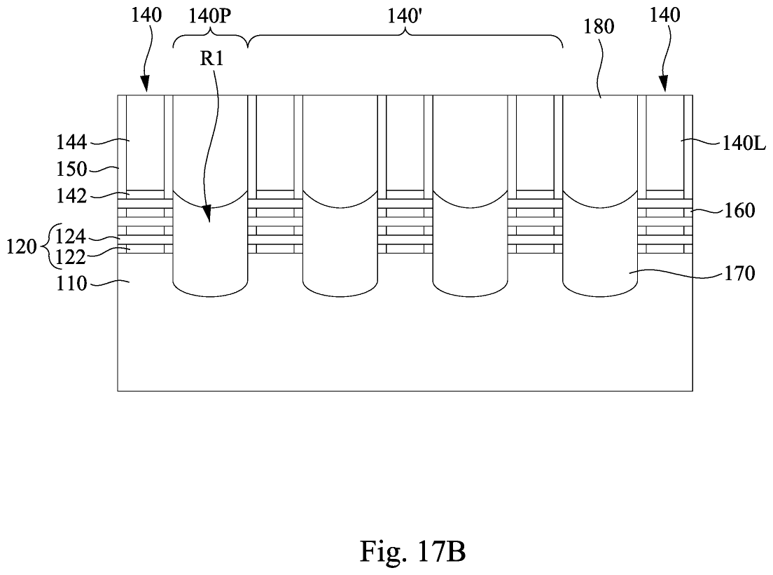

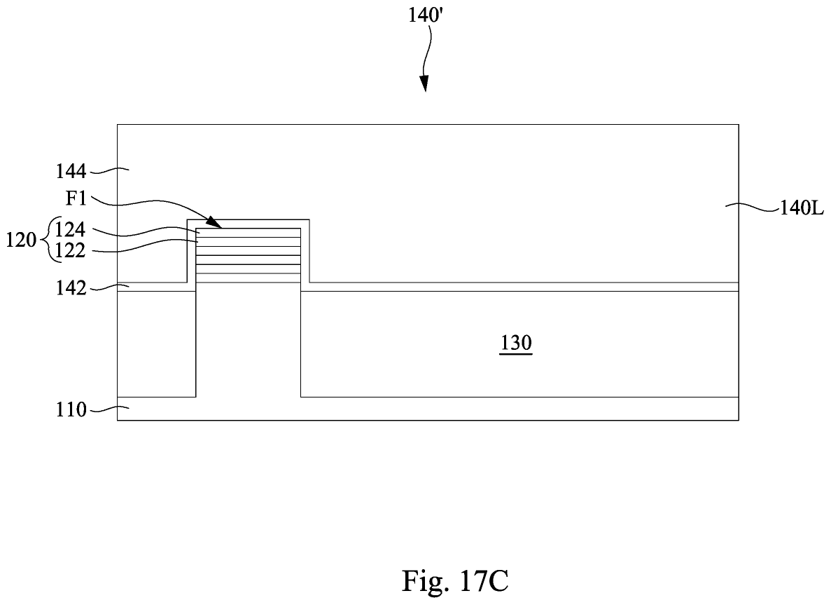

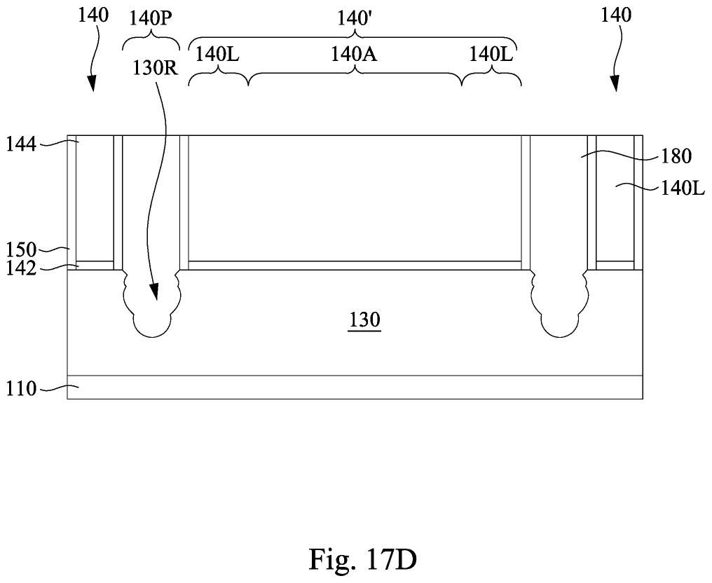

Reference is made to FIGS. 17A-17D. Exposed portions of the semiconductor fins F1 that extend laterally beyond sidewalls of the gate spacers 150 (e.g., in source/drain regions of the fins F1) are etched by using, for example, an anisotropic etching process that uses the dummy gate structure 140 and 140′ and the gate spacers 150 as an etch mask, resulting in recesses R1 into the semiconductor fins F1 and between corresponding dummy gate lines 140L. Subsequently, source/drain epitaxial structures 170 are formed in the recesses R1 in the fins F1.

As aforementioned, the etching process of forming the source/drain recess and the formation of the source/drain epitaxial structures 170 may consume oxides of the STI structures 130. For example, the STI structures 130 being consumed may have the recesses 130R in the exposed region. In absence of the auxiliary gate portions 140A, the recesses 130R may be wider and deeper. As the devices size shrinks (for example a width of the gate lines GL becomes less than about 20 nanometers), the poly line (e.g., the gate lines 140L) may collapse due to the oxide consume on the poly lines.

In some embodiments of the present disclosure, by using the auxiliary gate portions 140A providing structural support between the gate lines 140L, the stability of the poly lines is improved. Also, since the configuration of the auxiliary gate portions 140A limit the exposed region of STI structures 130, the etching processes and cleaning processes may not serious consume the STI structures 130. Through the configuration of the auxiliary gate portions 140A, poly line collapse can be avoided.

After the formation of source/drain epitaxial structures 170, an interlayer dielectric (ILD) layer 180 is deposited over the substrate 110 and filling the space between the dummy gate structures 140 and/or 140′ (e.g., the gate line spaces 140P). The ILD layer 180 may also fill the recesses 130R in the STI structures 130. A planarization process may be performed to remove excessive materials of the ILD layer 180. For example, a planarization process includes a CMP process which removes portions of the ILD layer 180 (and the CESL layer) overlying the dummy gate structures 140 and 140′ and planarizes a top surface of the IC structure. In some embodiments, the CMP process also removes the hard mask 146 in the dummy gate structures 140 and/or 140′ (as shown in FIGS. 16A-16D) and exposes the dummy gate electrode layer 144.

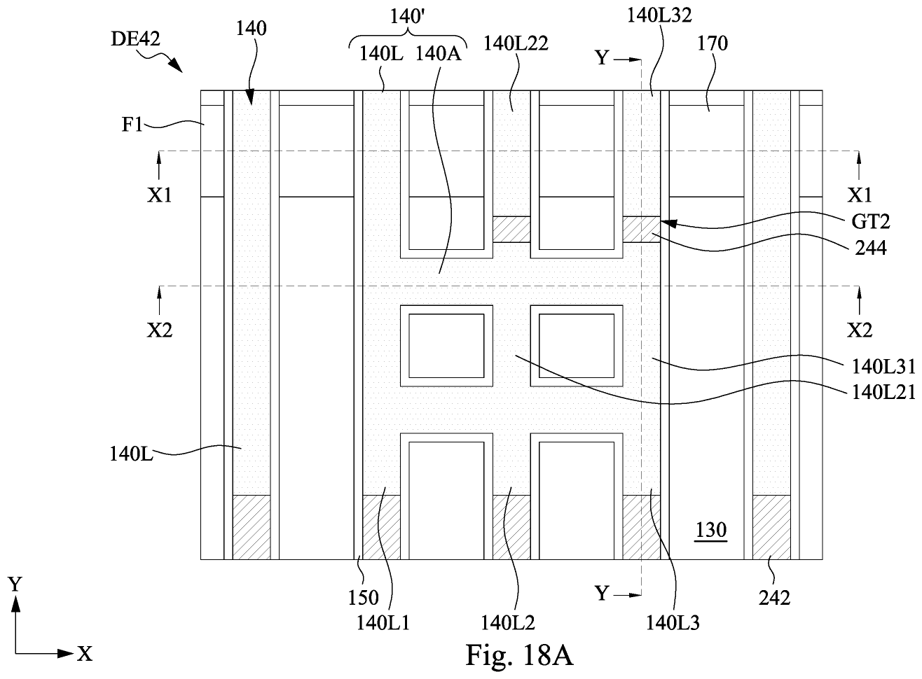

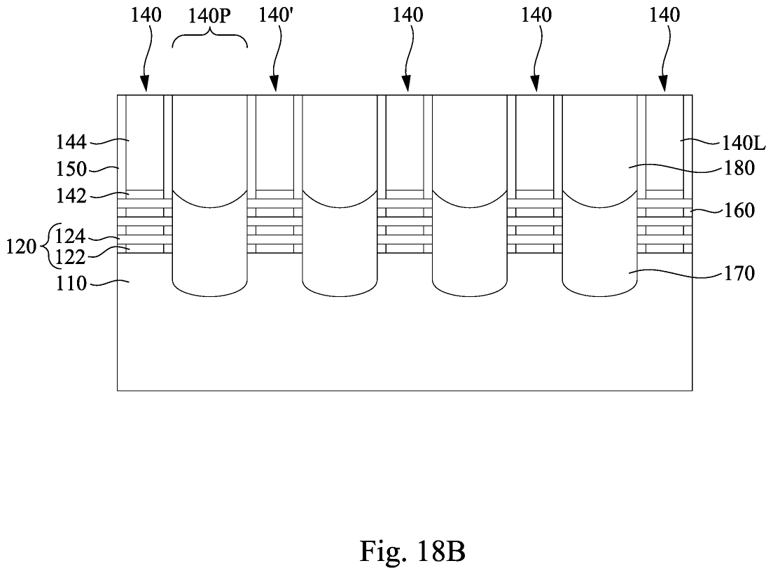

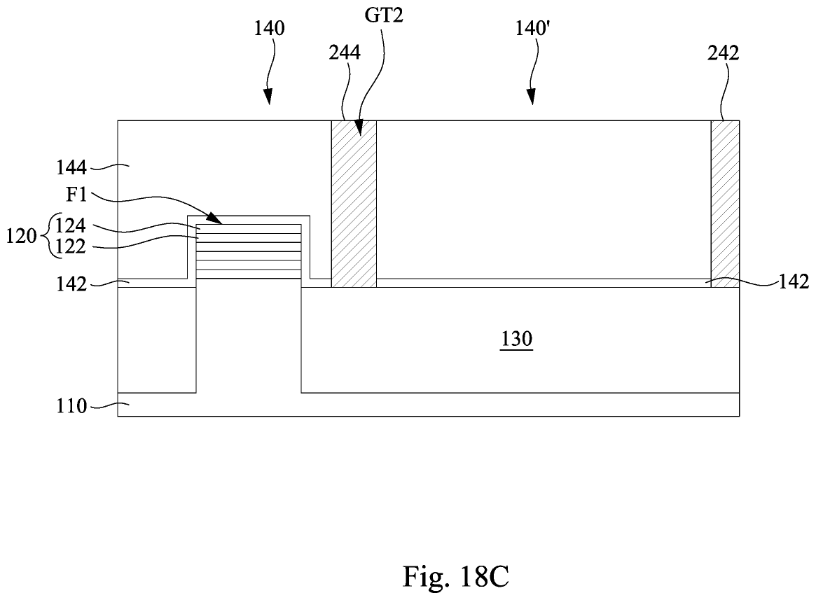

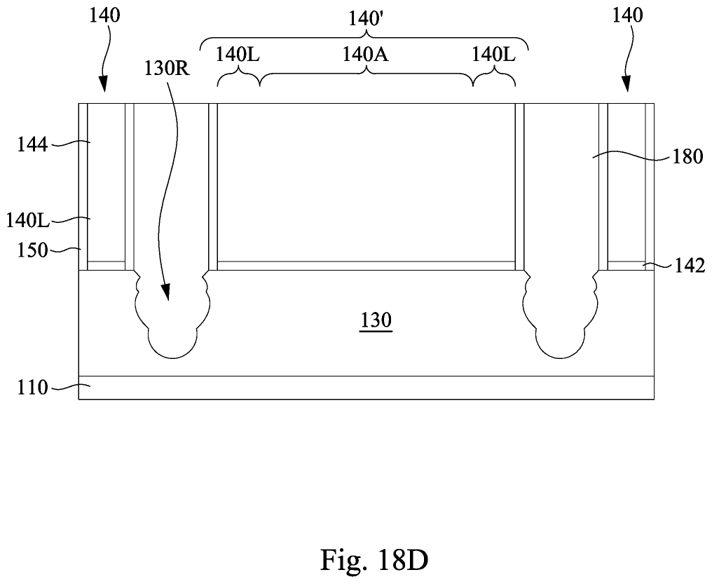

Reference is made to FIGS. 18A-18D. Gate isolation structures 242 and 244 are formed in the gate structure 140 and 140′. Formation of the gate isolation structures 242 and 244 includes removing a portion of the gate structure 140 and 140′ to leave a gate trench GT2 between the gate spacers 150, and depositing one or more dielectric materials to overfill the gate trench GT2. The removing process may include suitable lithography and one or more suitable etching processes. The one or more dielectric materials may include SiO₂, SiN, SiCN, SiCON, SiCO, AlO, HfO, the like, or the combination thereof. A CMP process may be performed to remove a portion of the dielectric material out of the gate trench GT2, and a remaining portion of the dielectric material in the gate trench GT2 forms the gate isolation structures 242 and 244. In some embodiments, when the hard mask 146 is in place, the CMP process may also remove the hard mask 146 in the dummy gate structures 140 and/or 140′ (as shown in FIGS. 16A-16D) and exposes the dummy gate electrode layer 144.

The gate isolation structures 244 may stop the gate structure 140′ from overlapping plural channel regions of the fin FS. For clear illustration, the dummy gate lines 140L of the gate structure 140′ are labelled as gate lines 140L1-140L3. The gate isolation structures 244 are formed in the dummy gate lines 140L2 and 140L3 of the gate structure 140′. The gate isolation structures 244 may cut the dummy gate line 140L2 of the gate structures 140′ into two separated first and second dummy gate line 140L21 and 140L22, and cut the dummy gate line 140L3 of the gate structures 140′ into two separated first and second dummy gate line 140L31 and 140L32. The auxiliary gate portions 140A connects the first dummy gate line 140L21, 140L31, and the dummy gate line 140L to each other. The second dummy gate line 140L22 and 140L32 are overlapping the fins FS and not connected with the auxiliary gate portions 140A. Through the configuration of the gate isolation structures 244, the gate structure 140′ is overlapping one channel region of the fin FS, and free of overlapping plural channel regions of the fin FS, thereby avoiding shorting among transistors.

In some embodiments, the gate isolation structures 242 are formed at ends of the dummy gate lines 140L of the gate structures 140 and 140′. The gate isolation structure 242 may be aligned with each other along the direction X and indicate a cell boundary.

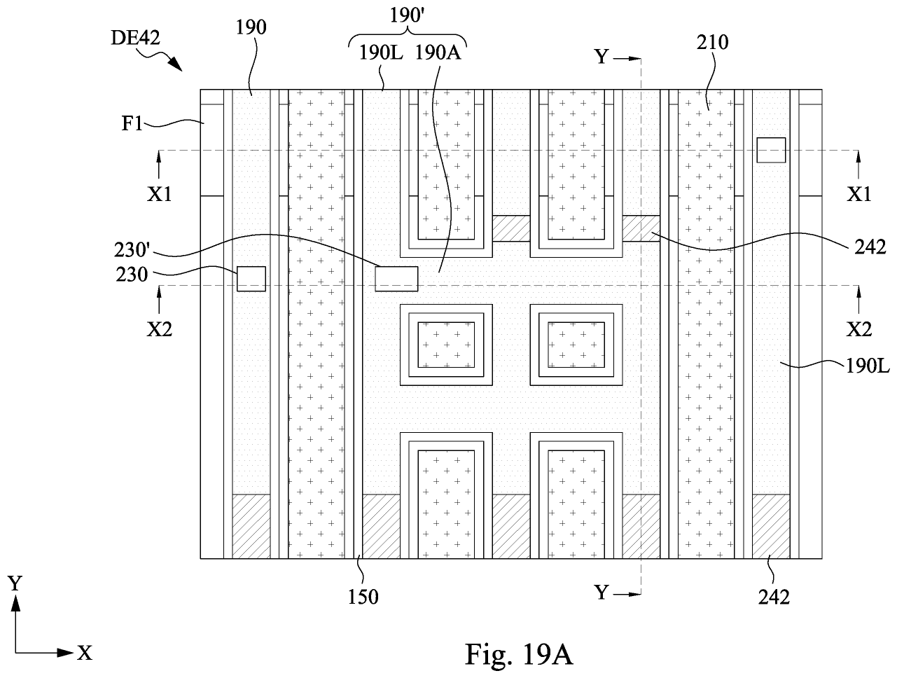

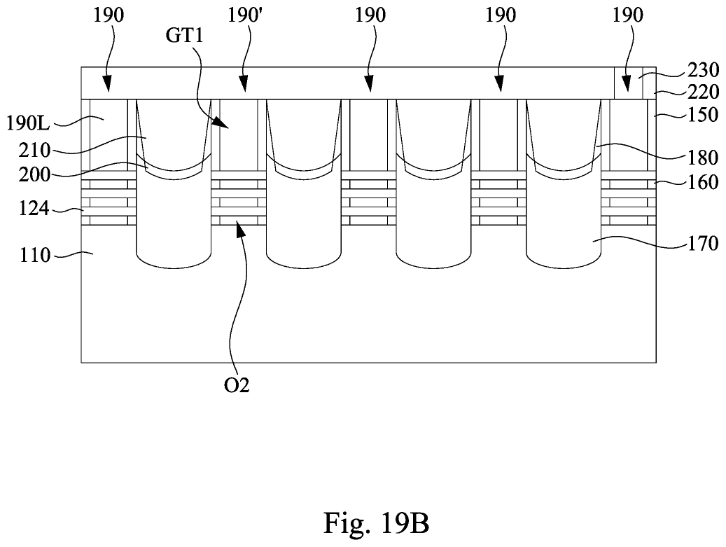

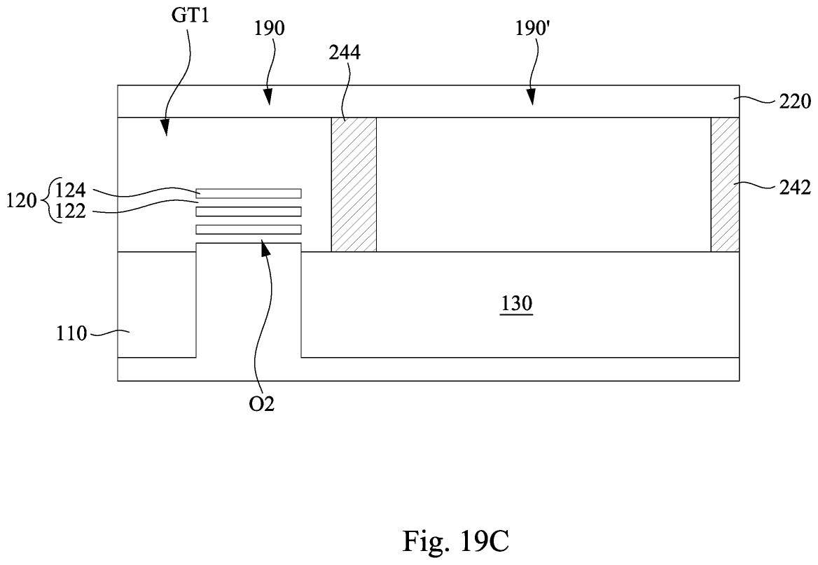

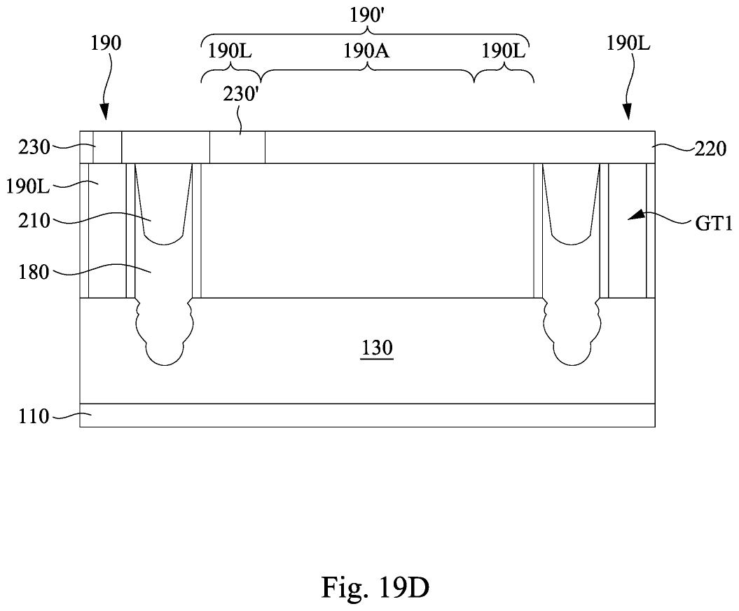

Reference is made to FIGS. 19A-19D. A gate replacement process is performed to replace the dummy gate structures 140 and 140′ and the sacrificial layers 122 (referring to FIGS. 13A-13D) with high-k/metal gate structures 190 and 190′. After the gate replacement process, source/drain contacts 210 are formed over the source/drain epitaxial structure 170. Gate contacts 230 and 230′ are formed over the gate structures 190 and 190′, respectively. Other details of the present disclosure are similar to those illustrated above, and thereto not repeated herein.

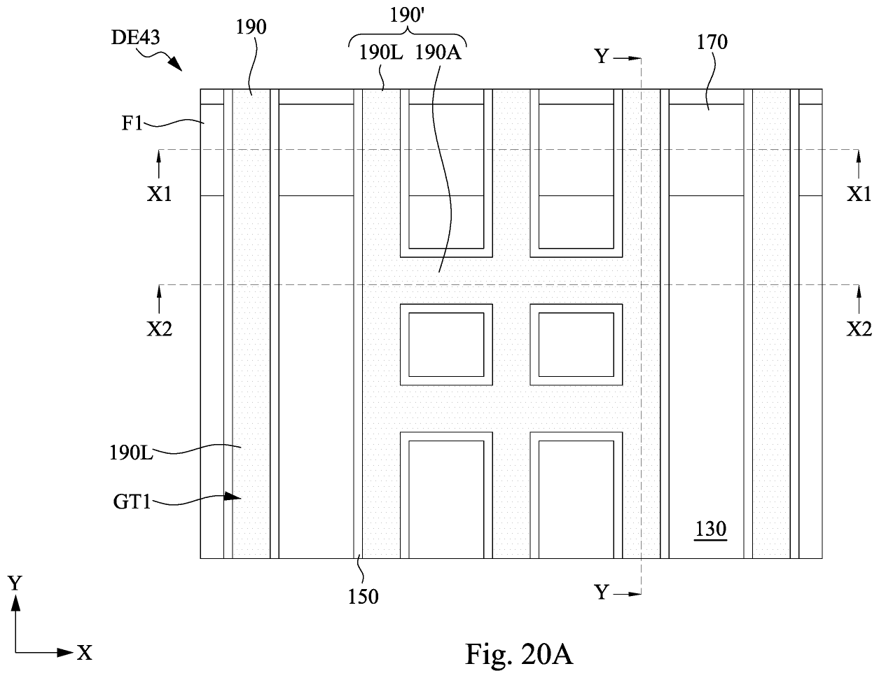

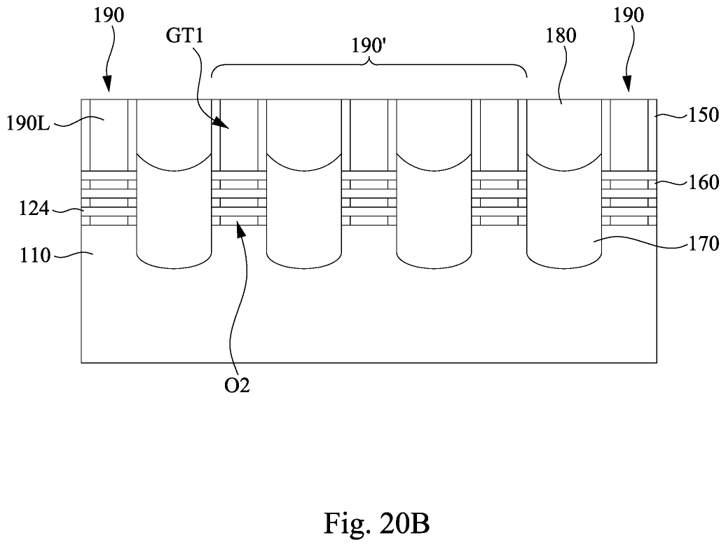

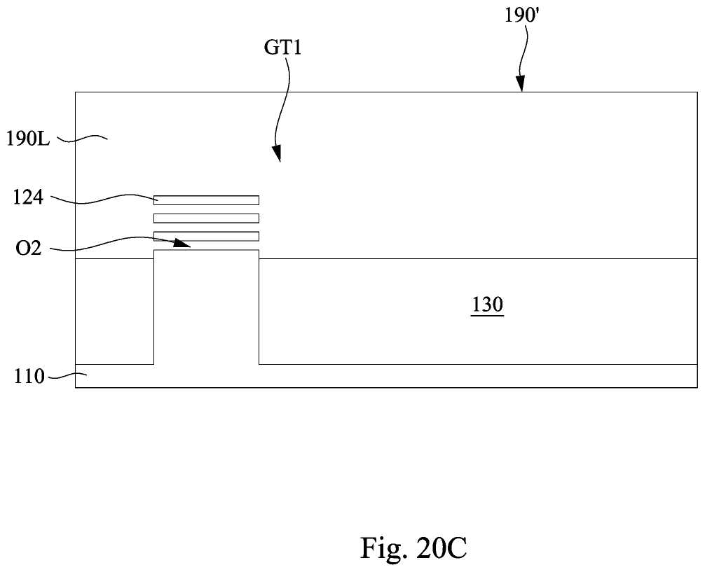

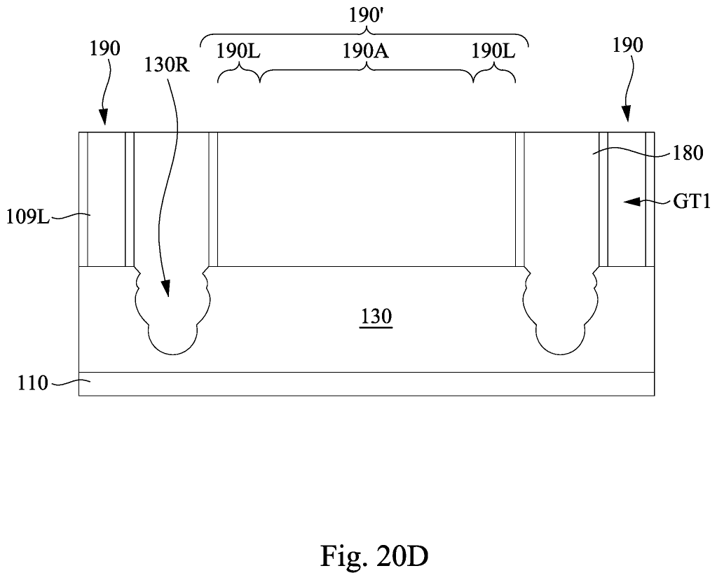

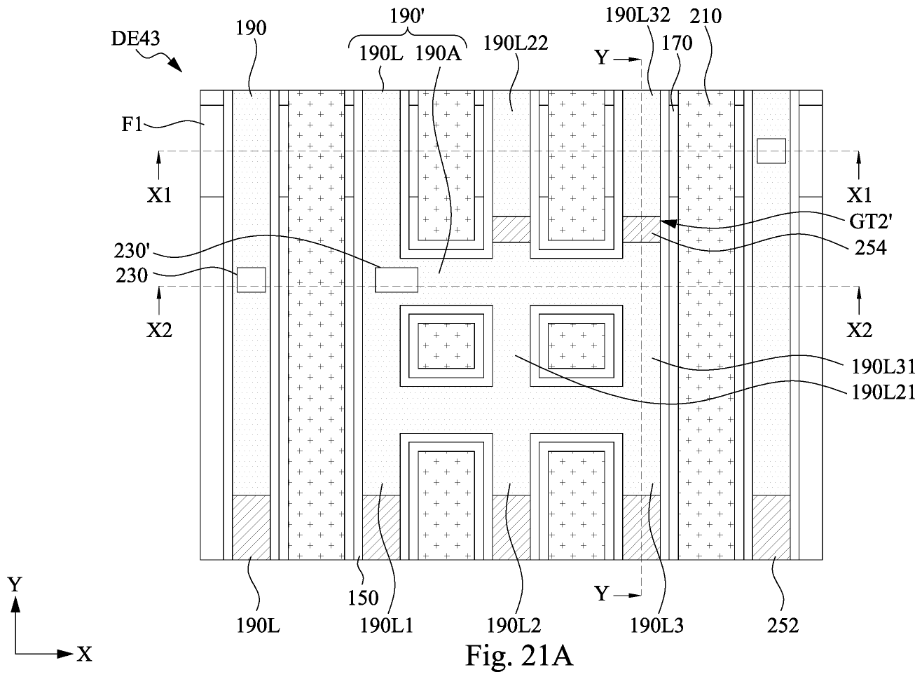

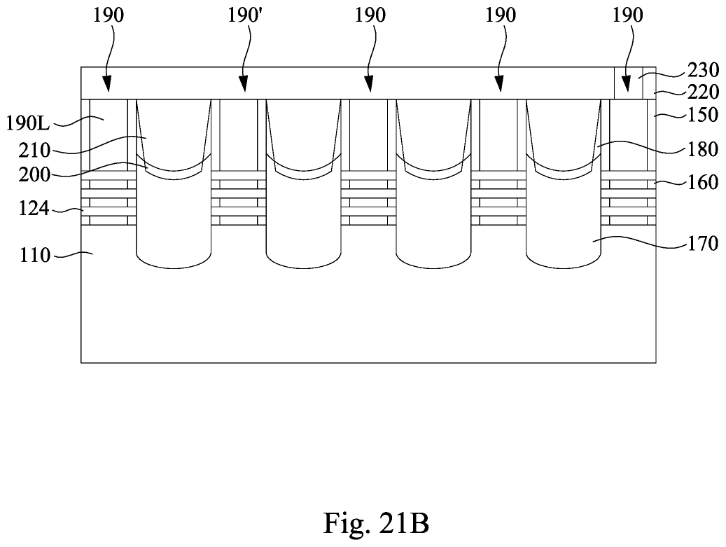

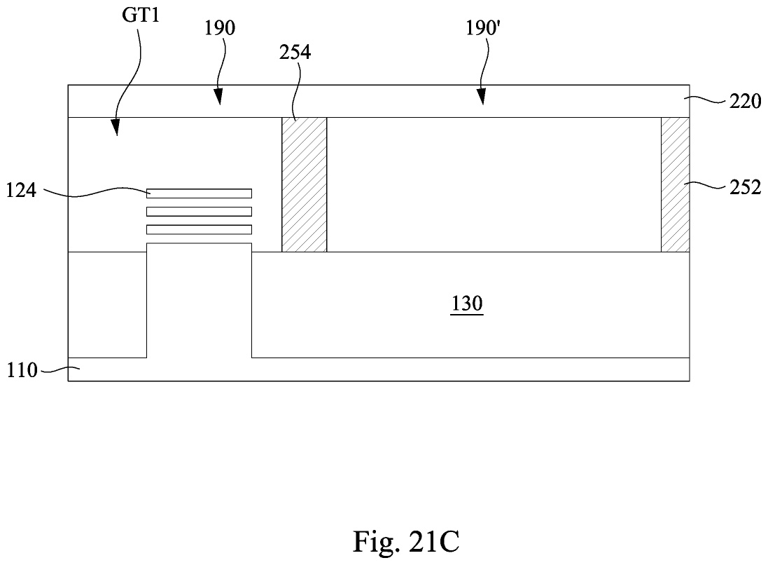

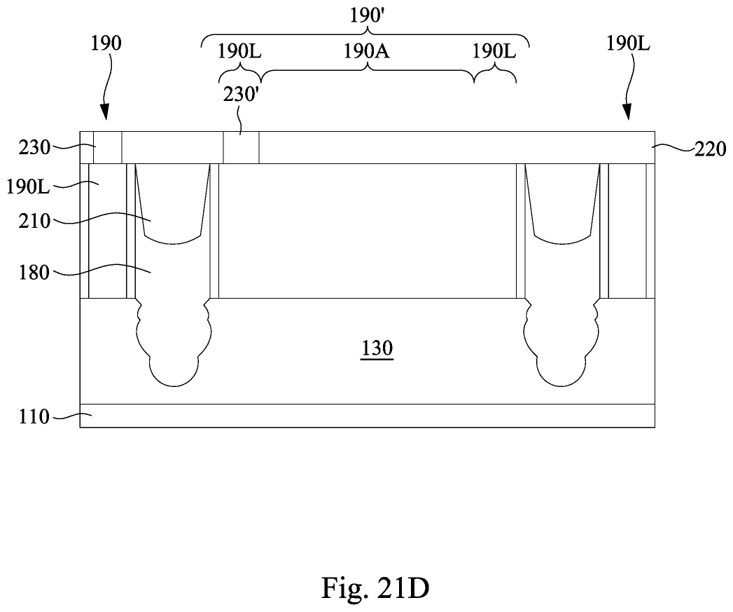

FIGS. 20A-21D illustrate various stages of fabricating an IC structure DE43 using the IC layout L4 of FIG. 8 according to some embodiments of the present disclosure. The IC structure DE43 inherits geometry of those patterns in the layout L4 of FIG. 8. The details of the present embodiments are similar to those illustrated in FIG. 9-15D and those illustrated in FIGS. 16A-19D, except that the gate lines are cut after the gate replacement process in the present embodiments. It is understood that additional operations may be provided before, during, and after the operations shown by FIGS. 20A-21D, and some of the operations described below can be replaced or eliminated for additional embodiments of the method. The order of the operations/processes may be interchangeable.

FIGS. 20A and 21A are top views of intermediate stages in the fabricating the IC structure DE43 in accordance with some embodiments of the present disclosure. FIGS. 20B and 21B are cross-sectional views of intermediate stages of fabricating the IC structure DE43 along a cut X1-X1 (referring to FIGS. 20A and 21A). FIGS. 20C and 21C are cross-sectional views of intermediate stages of fabricating the IC structure DE43 along a cut Y-Y (referring to FIGS. 20A and 21A). FIGS. 20D and 21D are cross-sectional views of intermediate stages of fabricating the IC structure DE43 along a cut X2-X2 (referring to FIGS. 20A and 21A).

Reference is made to FIGS. 20A-20D. Following the formation of the source/drain epitaxial structures as illustrated in FIGS. 17A-17D, a gate replacement process is performed to replace the dummy gate structures 140 and 140′ and the sacrificial layers 122 (referring to FIGS. 17A-17D) with high-k/metal gate structures 190 and 190′.

Reference is made to FIGS. 21A-21D. After the gate replacement process, gate isolation structures 252 and 254 are formed in the gate structure 190 and 190′. Formation of the gate isolation structures 252 and 254 includes removing a portion of the gate structure 190 and 190′ to leave a gate trench GT2′ between the gate spacers 150, and depositing one or more dielectric materials to overfill the gate trench GT2′. The removing process may include suitable lithography and one or more suitable etching processes. The one or more dielectric materials may include SiO₂, SiN, SiCN, SiCON, SiCO, AlO, HfO, the like, or the combination thereof. A CMP process may be performed to remove a portion of the dielectric material out of the gate trench GT2′, and a remaining portion of the dielectric material in the gate trench GT2′ forms the gate isolation structures 252 and 254.

The gate isolation structures 254 may stop the gate structure 190′ from overlapping plural channel regions of the fin FS. For clear illustration, the dummy gate lines 190L of the gate structure 190′ are labelled as gate lines 190L1-190L3. The gate isolation structures 254 are formed in the dummy gate lines 190L2 and 190L3 of the gate structure 190′. The gate isolation structures 254 may cut the dummy gate line 190L2 of the gate structures 190′ into two separated first and second dummy gate line 190L21 and 140L22, and cut the dummy gate line 190L3 of the gate structures 190′ into two separated first and second dummy gate line 190L31 and 190L32. The auxiliary gate portions 190A connects the first dummy gate line 190L21, 190L31, and the dummy gate line 190L to each other. The second dummy gate line 190L22 and 190L32 are overlapping the fins FS. Through the configuration of the gate isolation structures 254, the gate structure 190′ is overlapping one channel region of the fin FS, and free of overlapping plural channel regions of the fin FS, thereby avoiding shorting among transistors. In some embodiments, the gate isolation structures 252 are formed at ends of the dummy gate lines 190L of the gate structures 190 and 190′. The gate isolation structure 252 may be aligned with each other along the direction X and indicate a cell boundary.

Source/drain contacts 210 are formed over the source/drain epitaxial structure 170. Gate contacts 230 and 230′ are formed over the gate structures 190 and 190′, respectively. Other details of the present disclosure are similar to those illustrated above, and thereto not repeated herein.

FIG. 22 illustrates an IC layout L5 according to some embodiments of the present disclosure. Details of the IC layout L5 are similar to those illustrated in the IC layout L2 of FIG. 4A, except that the auxiliary gate patterns GAP (e.g., gate rivet patterns GRP) overlapping adjacent gate line patterns GLP are aligned with each other along the X direction. The gate line patterns GLP are labelled as gate line patterns GLP1-GLP5. For example, the auxiliary gate patterns GAP (e.g., gate rivet patterns GRP) overlapping the gate line patterns GLP2-GLP4 are aligned with each other along the X direction. The gate line patterns GLP1 and GLP5 may be spaced apart from the auxiliary gate patterns GAP (e.g., gate rivet patterns GRP). Other details of the present embodiments are similar to those illustrated above, and thereto not repeated herein.

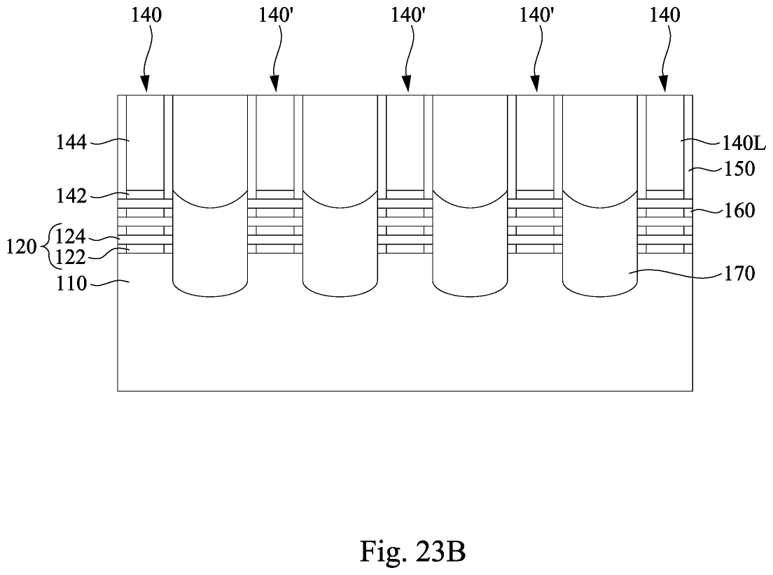

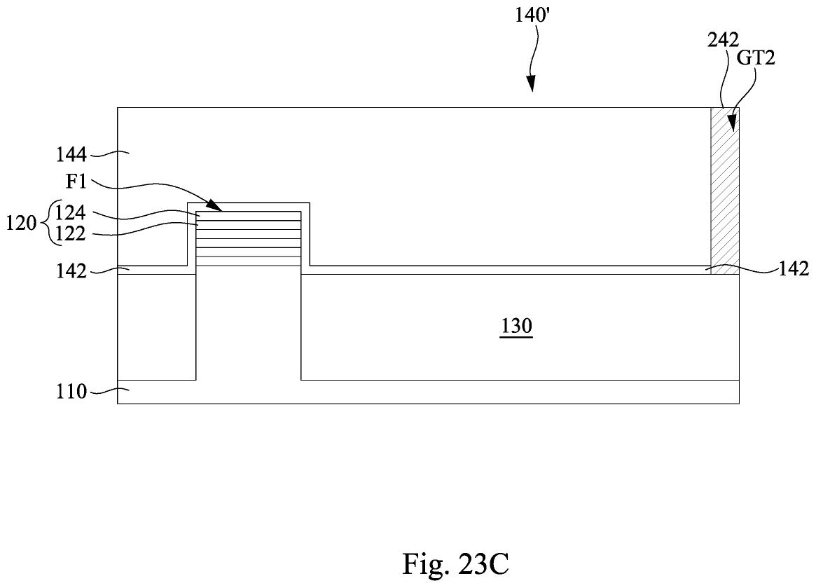

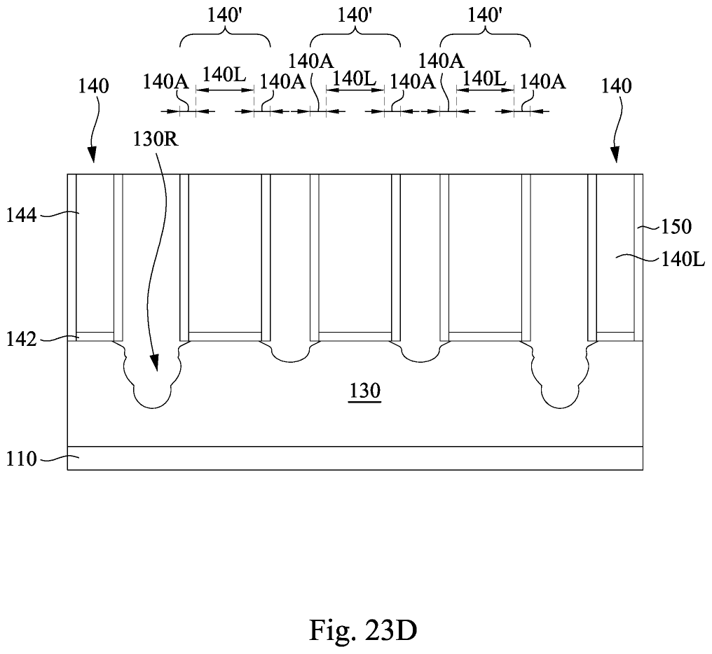

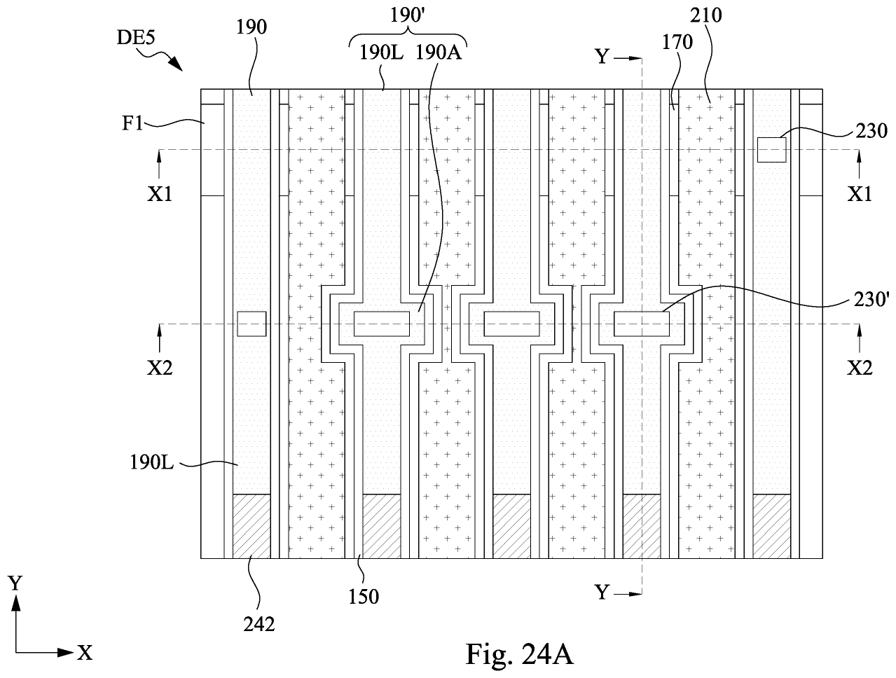

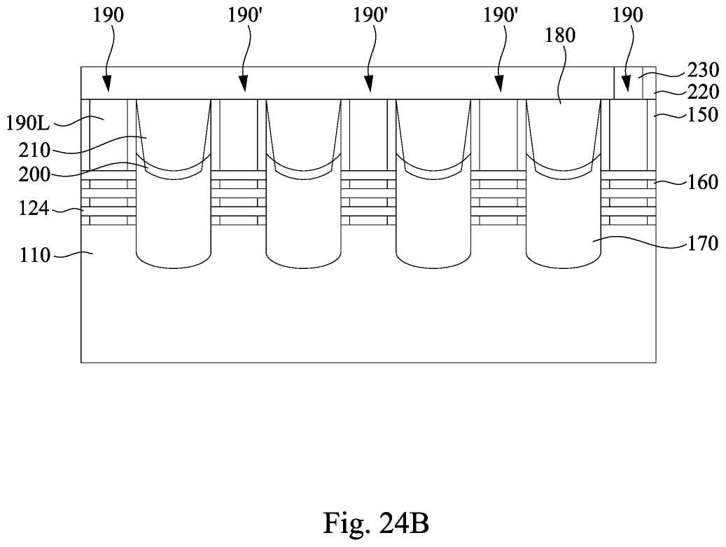

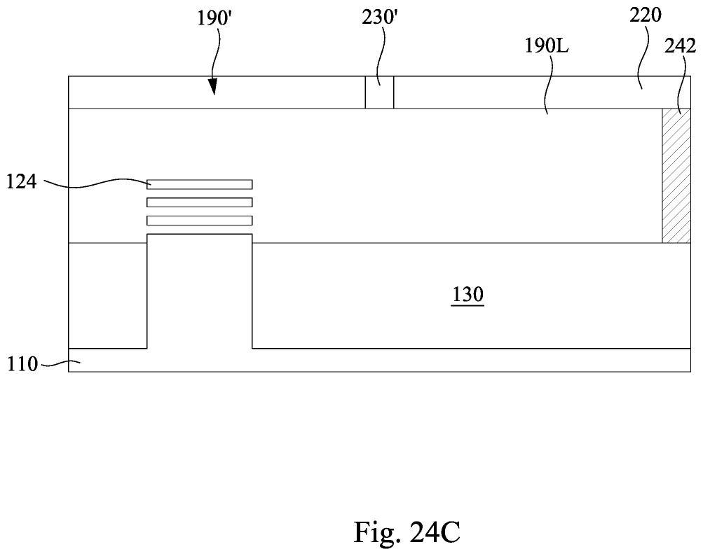

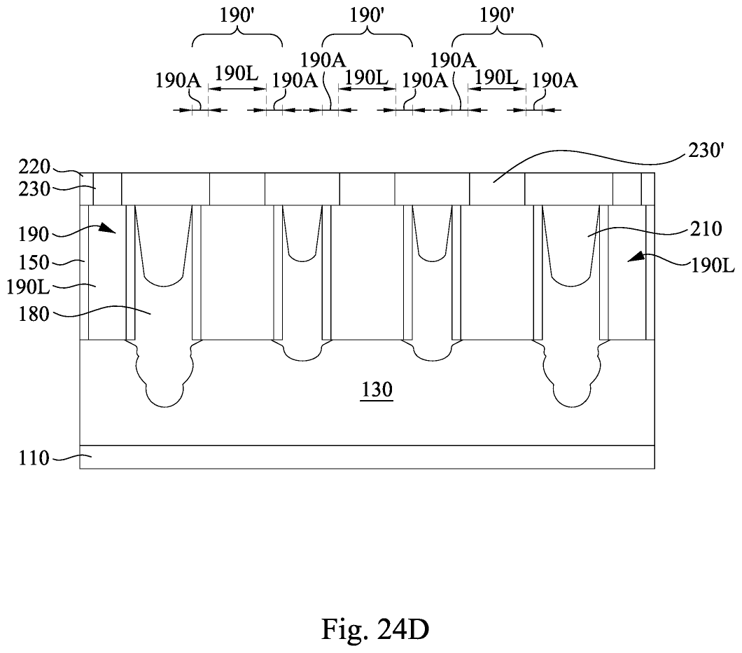

FIGS. 23A-24D illustrate various stages of fabricating an IC structure DE5 using the IC layout L5 of FIG. 22 according to some embodiments of the present disclosure. The IC structure DE5 inherits geometry of those patterns in the layout L5 of FIG. 22. The steps of the fabrication process are similar to those illustrated in FIGS. 16A-19D. It is understood that additional operations may be provided before, during, and after the operations shown by FIGS. 23A-24D, and some of the operations described below can be replaced or eliminated for additional embodiments of the method. The order of the operations/processes may be interchangeable.

FIGS. 23A and 24A are top views of intermediate stages in fabricating the IC structure DE5 in accordance with some embodiments of the present disclosure. FIGS. 23B and 24B are cross-sectional views of intermediate stages of fabricating the IC structure DE5 along a cut X1-X1 (referring to FIGS. 23A and 24A). FIGS. 23C and 24C are cross-sectional views of intermediate stages of fabricating the IC structure DE5 along a cut Y-Y (referring to FIGS. 23A and 24A). FIGS. 23D and 24D are cross-sectional views of intermediate stages of fabricating the IC structure DE5 along a cut X2-X2 (referring to FIGS. 23A and 24A).

Reference is made to FIGS. 23A-23D. Following the formation of the fins F1 as illustrated in FIGS. 10A-10C, plural dummy (sacrificial) gate structures 140 and 140′ are formed over the substrate 110. Each of the dummy gate structures 140 and 140′ may include gate lines 140L extending along substantially parallel to each other, for example, substantially long a direction Y. In the present embodiments, each of the gate lines 140L is at least partially over the fins F1, for example, extending across the fins F1. In some other embodiments, some of the gate lines 140L are at least partially over the fins F1, and the other of the gate lines 140L are entirely over the STI structures 130 and free of overlapping the fins F1. The formation of the dummy gate structures 140 and 140′ is similar to those illustrated above, and therefore not repeated herein. Due to etch loading, the hard mask 146 of the gate structure 140′ including the auxiliary gate portions 140A may have a higher top surface than a top surface of the hard mask 146 of the gate structure 140 as shown in FIG. 11D.

In some embodiments of the present disclosure, the dummy gate structures 140′ include auxiliary gate portions 140A extending from one or two sidewalls of one gate line 140L but not reach an adjacent gate line 140L. Through the configuration, the auxiliary gate portions 140A provide structural support to the gate line 140L, thereby avoiding poly collapse. In the context, the dummy gate structures with the auxiliary gate portions 140A are referred to as the dummy gate structure 140′, and the dummy gate structures without the auxiliary gate portions 140A are referred to as the dummy gate structure 140.

In the present embodiments, every two adjacent gate lines 140L are spaced from each other by a distance D1, and the auxiliary gate portions 140A extending beyond a sidewall of the gate line 140L by a distance D2 less than half the distance D1. This configuration allows the alignment between plural auxiliary gate portions 140A along the X direction. In some other embodiments where the auxiliary gate portions 140A is misaligned along the X direction (as shown in FIGS. 4A-5B and 7A-7B), the distance D2 may be less than, equal to, or greater than half the distance D1.

In some embodiments, the gate structure 140′ (i.e., a combination of the gate lines 140L and the auxiliary gate portions 140A) and/or the gate structure 140 (i.e., the gate line 140L) may be an active or operative gate structure, and for example, may overlap the fin F1. In some other embodiments, the gate structure 140′ (i.e., a combination of the gate lines 140L and the auxiliary gate portions 140A) and/or the gate structure 140 may be an inactive or non-operative gate structure, and may not overlap the fin F1 from the top view. For example, an entirety of the inactive or non-operative gate structure 140 and/or 140′ may be over the STI structures 130.

After the formation of the dummy gate structures 140 and 140′, gate spacers 150 are formed on sidewalls of the dummy gate structures 140 and 140′. After the formation of the gate spacers 150, the source/drain epitaxial structure 170 are formed over the fins F1. Then, gate isolation structures 242 and 244 are formed in the gate structure 140 and 140′.

Reference is made to FIGS. 24A-24D. A gate replacement process is performed to replace the dummy gate structures 140 and 140′ and the sacrificial layers 122 (referring to FIGS. 23A-23D) with high-k/metal gate structures 190 and 190′. As aforementioned, the dummy gate structures 140 and 140′ (referring to FIGS. 23A-23D) are first removed, which resulting in gate trenches GT1 between corresponding gate spacers 150. The sacrificial layers 122 (referring to FIGS. 13A-13D) are exposed in the gate trenches GTL. Subsequently, the sacrificial layers 122 (referring to FIGS. 13A-13D) in the gate trenches GT1 are etched, thereby forming openings/spaces O2 between neighboring channel layers 124. Replacement gate structures 190 and 190′ are formed in the gate trenches GT1 and the openings/spaces O2 to surround each of the nanosheets 124 suspended in the gate trenches GT1. Source/drain contacts 210 are formed over the source/drain epitaxial structure 170. Gate contacts 230 and 230′ are formed over the gate structures 190 and 190′, respectively. Other details of the present disclosure are similar to those illustrated above, and thereto not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that connecting auxiliary poly portions are added to connect plural vertical poly lines, thereby providing horizontal structural support to the vertical poly lines and preventing the vertical poly lines from collapse. Another advantage is that rivet auxiliary poly portions are added to enlarge areas of the poly lines and reduce space between the poly lines, thereby reducing the STI loss during the process. Still another advantage is that the gate structure with the auxiliary gate portion has a larger area to receive the gate contact, thereby increasing the area of the gate contact, which in turn will lower the resistance.

According to some embodiments of the present disclosure, an integrated circuit (IC) structure includes a semiconductor substrate, a first gate line, a second gate line, and a first auxiliary gate portion. The semiconductor substrate comprises a semiconductor fin. The semiconductor fin extends substantially along a first direction. The first gate line and the second gate line extend substantially along a second direction different form the first direction from a top view. The first auxiliary gate portion connects the first gate line to the second gate line from the top view.

According to some embodiments of the present disclosure, an integrated circuit (IC) structure includes a semiconductor substrate, a first gate line, a second gate line, and a first auxiliary gate portion. The semiconductor substrate comprises a semiconductor fin extending substantially along a first direction. The first gate line and the second gate line, wherein the first and second gate lines extend substantially along a second direction different from the first direction, and the second gate line is adjacent to a first sidewall of the first gate line. The first auxiliary gate portion extends from the first sidewall of the first gate line along the first direction from a top view. The first auxiliary gate portion is spaced apart from the second gate line.

According to some embodiments of the present disclosure, a method for fabricating an IC structure is provided. The method includes forming a semiconductor fin over a semiconductor substrate, wherein the semiconductor fin extends substantially along a first direction; forming an isolation structure around the semiconductor fin; and forming a first gate structure over the semiconductor substrate, wherein the first gate structure comprises a first gate line and a first auxiliary gate portion, the first gate line extends substantially along a second direction different from the first direction, and the first auxiliary gate portion is over the isolation structure and extends from a sidewall of the first gate line along the first direction from a top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a semiconductor substrate comprising a semiconductor fin, wherein the semiconductor fin extends substantially along a first direction;
a first gate line and a second gate line extending substantially along a second direction different from the first direction from a top view; and
a first auxiliary gate portion connecting the first gate line to the second gate line from the top view.

2. The IC structure of claim 1, wherein the first auxiliary gate portion is spaced apart from the semiconductor fin along the second direction from the top view.

3. The IC structure of claim 1, further comprising:
a gate contact having a first portion over one of the first and second gate lines and a second portion over the first auxiliary gate portion.

4. The IC structure of claim 1, wherein the first gate line extends across the semiconductor fin, and the second gate line does not extend across the semiconductor fin.

5. The IC structure of claim 1, further comprising:
a third gate line extending substantially along the second direction and across the semiconductor fin, wherein the third gate line is aligned with the second gate line along the second direction.

6. The IC structure of claim 1, further comprising a fourth gate line extending substantially along the second direction, and the first auxiliary gate portion connects the fourth gate line to the first and second gate lines.

7. The IC structure of claim 1, further comprising a second auxiliary gate portion connecting the first gate line to the second gate line.

8. The IC structure of claim 1, wherein one of the first and second gate lines extends beyond opposite sides of the first auxiliary gate portion along the second direction.

9. An IC structure, comprising:
a semiconductor substrate comprising a semiconductor fin extending substantially along a first direction;
a first gate line and a second gate line, wherein the first and second gate lines extend substantially along a second direction different from the first direction, and the second gate line is adjacent to a first sidewall of the first gate line; and
a first auxiliary gate portion extending from the first sidewall of the first gate line along the first direction from a top view, wherein the first auxiliary gate portion is spaced apart from the second gate line.

10. The IC structure of claim 9, further comprising an isolation structure surrounding the semiconductor fin, and the first auxiliary gate portion is over the isolation structure.

11. The IC structure of claim 9, wherein the first gate line extends across the semiconductor fin, and the first auxiliary gate portion is spaced apart from the semiconductor fin along the second direction from a top view.

12. The IC structure of claim 9, further comprising:
a gate contact having a first portion over the first gate line and a second portion over the first auxiliary gate portion.

13. The IC structure of claim 9, further comprising a second auxiliary gate portion extending from a sidewall of the second gate line along the first direction, and the second auxiliary gate portion is misaligned with the first auxiliary gate portion along the first direction.

14. The IC structure of claim 9, further comprising a second auxiliary gate portion extending from a sidewall of the second gate line along the first direction, and the second auxiliary gate portion is aligned with the first auxiliary gate portion along the first direction.

15. The IC structure of claim 9, wherein further comprising:
a third gate line extending substantially along the second direction, wherein the third gate line is immediately adjacent to a second sidewall of the first gate line, and the first auxiliary gate portion connects the first gate line to the third gate line.

16. A method for fabricating an IC structure, comprising:
forming a semiconductor fin over a semiconductor substrate, wherein the semiconductor fin extends substantially along a first direction;
forming an isolation structure around the semiconductor fin; and
forming a first gate structure over the semiconductor substrate, wherein the first gate structure comprises a first gate line and an auxiliary gate portion, the first gate line extends substantially along a second direction different from the first direction, and the auxiliary gate portion is over the isolation structure and extends from a sidewall of the first gate line along the first direction from a top view.

17. The method of claim 16, further comprising:
forming a gate contact, wherein the gate contact has a first portion over the first gate line and a second portion over the auxiliary gate portion.

18. The method of claim 16, wherein the first gate line extends across the semiconductor fin.

19. The method of claim 16, wherein forming the first gate structure is performed such that the first gate structure further comprises a second gate line, and the auxiliary gate portion extend from the sidewall of the first gate line along the first direction to a sidewall of the second gate line from a top view.

20. The method of claim 16, further comprising:
forming a second gate structure over the semiconductor substrate, wherein the second gate structure is immediately adjacent to the sidewall of the first gate line, and the auxiliary gate portion is free of contacting the second gate structure.
